(19) United States
(12) Patent Application Publication
(10) Pub. No.: US 2026/0304903 A1
(43) Pub. Date: Oct. 1, 2026

(54) NITRIDE SEMICONDUCTOR DEVICE

(71) Applicant: ROHM CO., LTD., Kyoto-shi (JP)

(72) Inventors: Manabu YANAGIHARA, Kyoto-shi (JP); Hirotaka OTAKE, Kyoto-shi (JP)

(73) Assignee: ROHM CO., LTD., Kyoto-shi (JP)

(21) Appl. No.: 19/577,364

(22) Filed: Mar. 25, 2026

(30) Foreign Application Priority Data
Mar. 27, 2025 (JP) 2025-053397
Jan. 26, 2026 (JP) 2026-010396

(51) Int. Cl. H10D 64/27; H10D 30/47; H10D 62/10; H10D 64/00; H10D 84/82

(52) U.S. Cl. CPC H10D 64/529; H10D 30/471; H10D 62/126; H10D 84/82; H10D 64/111

(57) ABSTRACT

A nitride semiconductor device includes a semiconductor substrate, an electron transit layer, an electron supply layer, a gate layer, a gate electrode, a source electrode, and a drain electrode. The nitride semiconductor device includes a cell region in which a transistor, including the gate electrode, the source electrode, and the drain electrode, is arranged. A peripheral region surrounds the cell region in plan view. A nitride semiconductor layer, formed from a nitride semiconductor including an acceptor impurity, is located in the peripheral region. A second peripheral electrode is located above the nitride semiconductor layer. A first peripheral electrode is located in the peripheral region. The first peripheral electrode is electrically connected to the gate electrode. The second peripheral electrode is electrically connected to the source electrode.

### CROSS-REFERENCE TO RELATED APPLICATIONS

This application is based upon and claims the benefit of priority from Japanese Patent Application No. 2025-053397, filed on Mar. 27, 2025, and Japanese Patent Application No. 2026-010396, filed on Jan. 26, 2026, the entire contents of each are incorporated herein by reference.

### BACKGROUND

### 1. Field

The following description relates to a nitride semiconductor device.

### 2. Description of Related Art

A high-electron-mobility transistor (HEMT), a nitride semiconductor device based on a III-V semiconductor such as gallium nitride (GaN), is currently being commercialized. A HEMT uses two-dimensional electron gas (2DEG) formed as a conduction path, or channel, near a semiconductor heterojunction interface (refer to, for example, JP2017-73506A). A power transistor using a HEMT has a low on-resistance and is operable at a higher speed and higher frequency than a typical silicon (Si) power transistor.

### BRIEF DESCRIPTION OF DRAWINGS

FIG. 1 is a schematic plan view of an exemplary nitride semiconductor device in accordance with a first embodiment.

FIG. 2 is a schematic cross-sectional view of the nitride semiconductor device taken along line F2-F2 in FIG. 1.

FIG. 3 is an enlarged, schematic cross-sectional view showing part of a cell region in the nitride semiconductor device illustrated in FIG. 2.

FIG. 4 is a schematic plan view showing the nitride semiconductor device of FIG. 1 without a protective layer, a third insulating layer, drain pads, source pads, and gate pads.

FIG. 5 is a schematic plan view showing the nitride semiconductor device of FIG. 4 without a second insulating layer, drain wiring, source wiring, and gate wiring.

FIG. 6 is an enlarged, schematic cross-sectional view showing a peripheral region of the nitride semiconductor device illustrated in FIG. 2.

FIG. 7 is a schematic diagram showing the electrical connection structure of the nitride semiconductor device illustrated in FIG. 1.

FIG. 8 is a schematic cross-sectional view of the nitride semiconductor device taken along line F8-F8 in FIG. 1.

FIG. 9 is a schematic cross-sectional view of the nitride semiconductor device taken along line F9-F9 in FIG. 1.

FIG. 10 is a schematic circuit diagram of the nitride semiconductor device illustrated in FIG. 1.

FIG. 11 is a schematic cross-sectional view exemplifying a manufacturing step of the nitride semiconductor device in accordance with the first embodiment.

FIG. 12 is a schematic cross-sectional view illustrating a manufacturing step following the step of FIG. 11.

FIG. 13 is a schematic cross-sectional view illustrating a manufacturing step following the step of FIG. 12.

FIG. 14 is a schematic cross-sectional view illustrating a manufacturing step following the step of FIG. 13.

FIG. 15 is a schematic cross-sectional view illustrating a manufacturing step following the step of FIG. 14.

FIG. 16 is a schematic cross-sectional view illustrating a manufacturing step following the step of FIG. 15.

FIG. 17 is a schematic plan view of an exemplary nitride semiconductor device in accordance with a second embodiment.

FIG. 18 is a schematic plan view showing the nitride semiconductor device of FIG. 17 without a protective layer, a third insulating layer, drain pads, source pads, and gate pads.

FIG. 19 is a schematic plan view showing the nitride semiconductor device of FIG. 18 without a second insulating layer, drain wiring, source wiring, and gate wiring.

FIG. 20 is a schematic cross-sectional view of the nitride semiconductor device taken along line F20-F20 in FIG. 17.

FIG. 21 is a schematic plan view of an exemplary nitride semiconductor device in accordance with a third embodiment.

FIG. 22 is a schematic plan view showing the nitride semiconductor device of FIG. 21 without a protective layer, a third insulating layer, drain pads, source pads, and gate pads.

FIG. 23 is a schematic plan view showing the nitride semiconductor device of FIG. 22 without a second insulating layer, drain wiring, source wiring, and gate wiring.

FIG. 24 is a schematic cross-sectional view of the nitride semiconductor device taken along line F24-F24 in FIG. 21.

FIG. 25 is a schematic cross-sectional view of the nitride semiconductor device taken along line F25-F25 in FIG. 21.

FIG. 26 is a schematic cross-sectional view exemplifying a manufacturing step of the nitride semiconductor device in accordance with the third embodiment.

FIG. 27 is a schematic circuit diagram of the nitride semiconductor device illustrated in FIG. 21.

FIG. 28 is a schematic diagram showing the electrical connection structure of an exemplary nitride semiconductor device in accordance with a fourth embodiment.

FIG. 29 is a schematic cross-sectional view of the nitride semiconductor device illustrated in FIG. 28.

FIG. 30 is an enlarged, schematic cross-sectional view showing the peripheral region of a modified nitride semiconductor device.

FIG. 31 is an enlarged, schematic cross-sectional view showing the peripheral region of a modified nitride semiconductor device.

FIG. 32 is an enlarged, schematic cross-sectional view showing the peripheral region of a modified nitride semiconductor device.

FIG. 33 is an enlarged, schematic cross-sectional view showing the peripheral region of a modified nitride semiconductor device.

### DETAILED DESCRIPTION

This description provides a comprehensive understanding of the methods, apparatuses, and/or systems described. Modifications and equivalents of the methods, apparatuses, and/or systems described are apparent to one of ordinary skill in the art. Sequences of operations are exemplary, and may be changed as apparent to one of ordinary skill in the art, with the exception of operations necessarily occurring in a certain order. Descriptions of functions and constructions that are well known to one of ordinary skill in the art may be omitted.

Exemplary embodiments may have different forms, and are not limited to the examples described. However, the examples described are thorough and complete, and convey the full scope of the disclosure to one of ordinary skill in the art.

In this specification, “at least one of A and B” should be understood to mean “only A, only B, or both A and B.”

Several embodiments of a nitride semiconductor device in accordance with the present disclosure will now be described with reference to the accompanying drawings. Elements in the figures are illustrated for simplicity and clarity and have not necessarily been drawn to scale. To facilitate understanding, hatching lines may not be shown in the cross-sectional drawings. The accompanying drawings illustrate exemplary embodiments in accordance with the present disclosure and are not intended to limit the present disclosure.

The detailed description hereafter provides a comprehensive understanding of exemplary methods, apparatuses, and/or systems in accordance with the present disclosure. This detailed description is illustrative and is not intended to limit embodiments of the present disclosure or the application and use of the embodiments.

Terms such as “first,” “second,” and “third” in this disclosure are used to distinguish subjects and not used for ordinal purposes.

In this specification, the phrase “at least one of” as used in this disclosure means “one or more” of a desired choice. As one example, the phrase “at least one of” as used in this disclosure means “only one of the two choices” or “both of the two choices” in a case where the number of choices is two. In another example, the phrase “at least one of” as used in this disclosure means “only one single choice” or “any combination of two or more choices” if the number of its choices is three or more.

In this specification, “the dimension (depth, width, length) of A is equal to the dimension (depth, width, length) of B,” and “the dimension (depth, width, length) of A and the dimension (depth, width, length) of B are equal” includes a relationship in which the difference between the dimension (depth, width, length) of A and the dimension (depth, width, length) of B is, for example, within 10% of the dimension (depth, width, length) of A.

### FIRST EMBODIMENT

### Outer Structure of Nitride Semiconductor Device

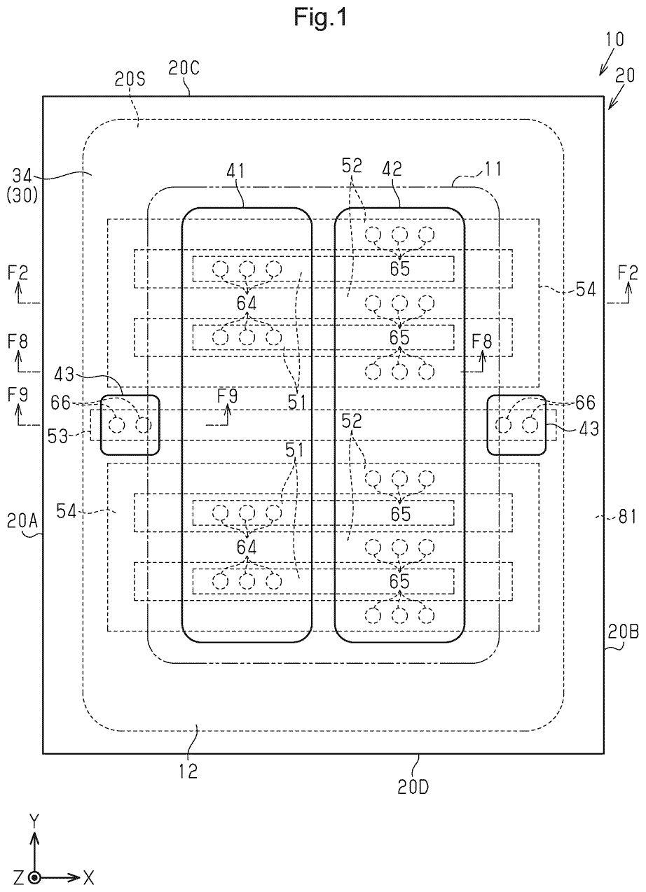

With reference to FIG. 1, the outer structure of a nitride semiconductor device 10 in accordance with a first embodiment will now be described. FIG. 1 schematically shows the plan structure of the nitride semiconductor device 10 in accordance with the first embodiment.

Elements may be described with reference to the X, Y, and Z axes that are orthogonal to one another and indicated in the drawings. The direction in which the X-axis extends is referred to as the X-direction, the direction in which the Y-axis extends is referred to as the Y-direction, and the direction in which the Z-axis extends is referred to as the Z-direction. The term “plan view” as used in the present description refers to a view of the nitride semiconductor device 10 taken in the Z-direction. The X-direction corresponds to a first direction, and the Y-direction corresponds to a second direction.

The nitride semiconductor device 10 shown in FIG. 1 is a high-electron-mobility transistor (HEMT) that uses a nitride semiconductor. A representative example of a nitride semiconductor includes gallium nitride (GaN), aluminum nitride (AlN), and indium nitride (InN), generally expressed as AlₓIn_{y}Ga_{1-x-y}N (0≤x≤1, 0≤y≤1, 0≤x+y≤1). The nitride semiconductor device 10 has the form of a plate of which the thickness direction is the Z-direction. The nitride semiconductor device 10 is quadrilateral in plan view. The nitride semiconductor device 10 includes a cell region 11 and a peripheral region 12 surrounding the cell region 11 in plan view. The cell region 11 is quadrilateral, in plan view, as shown by the double-dashed line. The cell region 11 is where transistors are arranged in the nitride semiconductor device 10. The peripheral region 12 has a looped quadrilateral shape in plan view. The cell region 11 and the peripheral region 12 may have any shape in plan view.

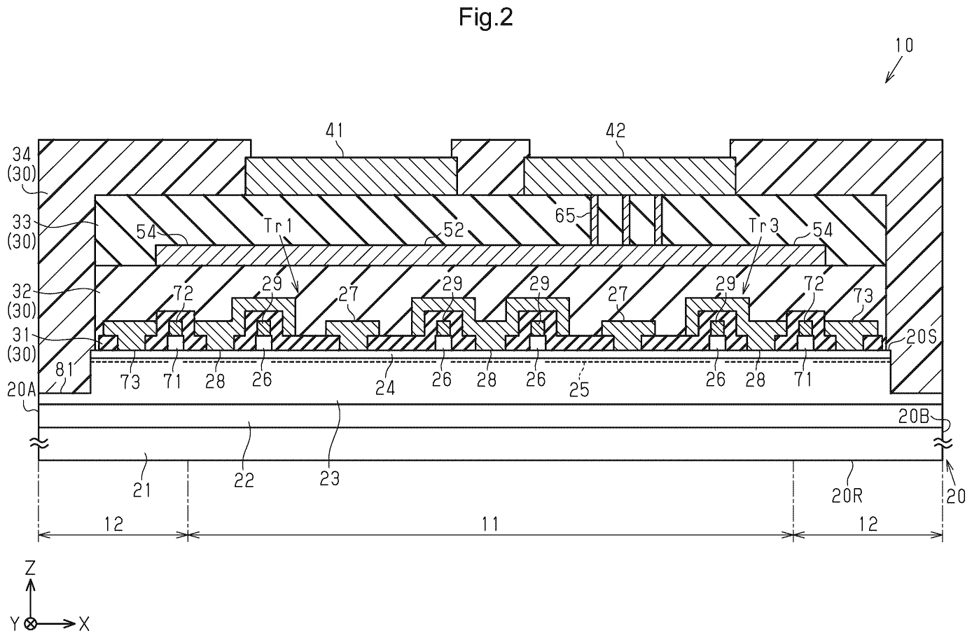

The nitride semiconductor device 10 includes a semiconductor layer 20. The semiconductor layer 20 has the form of a flat plate of which the thickness direction is the Z-direction. The semiconductor layer 20 is quadrilateral in plan view. The semiconductor layer 20 includes a first surface 20S, a second surface 20R (refer to FIG. 2) opposite the first surface 20S, and first to fourth side surfaces 20A to 20D connecting the first surface 20S and the second surface 20R. The first side surface 20A and the second side surface 20B define the two X-direction end surfaces of the semiconductor layer 20. The third side surface 20C and the fourth side surface 20D define the two Y-direction end surfaces of the semiconductor layer 20.

The nitride semiconductor device 10 includes an insulating layer 30 arranged above the first surface 20S of the semiconductor layer 20. The insulating layer 30 is arranged over both the cell region 11 and the peripheral region 12. The insulating layer 30 may include at least one of silicon oxide (SiO₂), silicon nitride (SiN), silicon oxynitride (SiON), and aluminum oxide (Al₂O₃). The insulating layer 30 may be formed by a single insulation layer or by a stack of insulation layers. In the first embodiment, the insulating layer 30 is a stack of insulation layers formed from different materials. The insulating layer 30 will be described later in detail together with the cross-sectional structure of the nitride semiconductor device 10.

The nitride semiconductor device 10 includes a drain pad 41, a source pad 42, and a gate pad 43 on the first surface 20S of the semiconductor layer 20. The drain pad 41, the source pad 42, and the gate pad 43 are located at the side of the first surface 20S opposite the second surface 20R and are separated from the first surface 20S in the Z-direction. In an example, the drain pad 41, the source pad 42 and the gate pad 43 are arranged in the insulating layer 30. The drain pad 41 and the source pad 42 both overlap the cell region 11 in plan view. At least part of the gate pad 43 overlaps the peripheral region 12 in plan view. In the example shown in FIG. 1, the gate pad 43 overlaps both the cell region 11 and the peripheral region 12 in plan view. The gate pad 43 may be located at any position. In an example, the gate pad 43 may overlap the peripheral region 12 and not overlap the cell region 11 in plan view.

The drain pad 41 and the source pad 42 are arranged next to each other in the X-direction. The drain pad 41 and the source pad 42 are each substantially quadrilateral, with long sides extending in the Y-direction and short sides extending in the X-direction. A large part of the cell region 11 is covered by the drain pad 41 and the source pad 42. The drain pad 41 and the source pad 42 may have any shape and any area in plan view. Further, the drain pad 41 and the source pad 42 may have any positional relationship.

The gate pad 43 is one of a plurality of gate pads 43. In the first embodiment, two gate pads 43 are arranged separated from each other in the X-direction. The drain pad 41 and the source pad 42 are both located between the two gate pads 43 in the X-direction. The two gate pads 43 are located at the central part of the semiconductor layer 20 in plan view with respect to the Y-direction. Each gate pad 43 is quadrilateral in plan view. In plan view, each gate pad 43 has an area that is smaller than the area of the drain pad 41 and smaller than the area of the source pad 42.

The drain pad 41, the source pad 42, and the gate pads 43 are formed from a conductive material. For example, the conductive material may include at least one of aluminum (Al), copper (Cu), an aluminum alloy, a copper alloy, tungsten (W), molybdenum (Mo), nickel (Ni), titanium (Ti), titanium nitride (TiN), tantalum (Ta), and tantalum nitride (TaN). The drain pad 41, the source pad 42, and the gate pads 43 may each be formed by a single metal layer or a stack of metal layers. In an example, the drain pad 41, the source pad 42, and the gate pads 43 are formed from the same conductive material.

Cross-Sectional Structure of the Semiconductor Layer

With reference to FIG. 2, the cross-sectional structure of the semiconductor layer 20 will now be described. FIG. 2 is a schematic cross-sectional view of the nitride semiconductor device 10 taken along line F2-F2 in FIG. 1.

The semiconductor layer 20 includes a semiconductor substrate 21, a buffer layer 22, an electron transit layer 23, and an electron supply layer 24. The semiconductor layer 20 is a stack of the semiconductor substrate 21, the buffer layer 22, the electron transit layer 23, and the electron supply layer 24 arranged in this order. The buffer layer 22, the electron transit layer 23, and the electron supply layer 24 are formed from a nitride semiconductor.

The semiconductor substrate 21 may be formed from silicon (Si), silicon carbide (SiC), gallium nitride (GaN), sapphire, or other substrate materials. In an example, the semiconductor substrate 21 is a Si substrate. The semiconductor substrate 21 defines the second surface 20R of the semiconductor layer 20. The semiconductor substrate 21 has a thickness of, for example, between 200 μm and 1500 μm, inclusive. The Z-direction corresponds to the thickness direction of the semiconductor substrate 21.

The buffer layer 22 may be formed from any material that reduces wafer warping and cracking that would be caused by the difference in coefficient of thermal expansion between the semiconductor substrate 21 and the electron transit layer 23. The buffer layer 22 may include one or more nitride semiconductor layers. The buffer layer 22 is formed from a material including aluminum gallium nitride (AlGaN). The buffer layer 22 includes, for example, at least one of an AlGaN layer and a graded AlGaN layer having different aluminum (Al) compositions. For example, the buffer layer 22 may include a single AlGaN layer, a single AlGaN layer, a layer having an AlGaN/GaN superlattice structure, a layer having an AlN/AlGaN superlattice structure, or a layer having an AlN/GaN superlattice structure. The buffer layer 22 may include AlGaN layers having different compositions.

To reduce leakage current in the buffer layer 22, part of the buffer layer 22 may include an impurity so that the buffer layer 22 becomes semi-insulative. In this case, the impurity may be, for example, carbon (C) or iron (Fe).

The electron transit layer 23 is located above the semiconductor substrate 21. In an example, the electron transit layer 23 is located above the buffer layer 22. The electron transit layer 23 is in contact with the buffer layer 22. The electron transit layer 23 may be, for example, a GaN layer. The electron transit layer 23 may include one or more nitride semiconductor layers. To reduce leakage current in the electron transit layer 23, an acceptor impurity may be introduced into part of the electron transit layer 23 so that a region excluding the outermost part of the electron transit layer 23 defines a doped layer that is semi-insulative. The doped layer is formed by a material including GaN that is doped with an acceptor impurity. In this case, the acceptor impurity is, for example, C. The doped layer is arranged above the buffer layer 22. In an example, the doped layer is arranged in the electron transit layer 23 close to the buffer layer 22 in the Z-direction. In an example, the doped layer is in contact with the buffer layer 22.

The electron supply layer 24 is located above the electron transit layer 23. In an example, the electron supply layer 24 is in contact with the electron transit layer 23. The electron supply layer 24 defines the first surface 20S of the semiconductor layer 20. The electron supply layer 24 is formed from a nitride semiconductor having a larger band gap than the electron transit layer 23. The electron supply layer 24 may be, for example, an AlGaN layer. The bandgap becomes larger as the Al composition increases. Thus, the electron supply layer 24, which is an AlGaN layer, has a larger band gap than the electron transit layer 23, which is a GaN layer. In an example, the electron supply layer 24 is formed from AlₓGa₁₋ₓN having Al composition ratio x. In this case, Al composition ratio x is 0.1<x<0.4, preferably, 0.1<x<0.3. The electron supply layer 24 may be thinner than the electron transit layer 23.

The electron transit layer 23 and the electron supply layer 24 have bulk regions of different lattice constants. Thus, the nitride semiconductor (e.g., GaN) of the electron transit layer 23 and the nitride semiconductor (e.g., AlGaN) of the electron supply layer 24 form a lattice-mismatched heterojunction. The spontaneous polarization of the electron transit layer 23 and the electron supply layer 24 and the piezoelectric polarization resulting from the compression stress received by the heterojunction of the electron transit layer 23 cause the energy level of the conduction band of the electron transit layer 23 to be lower than the Fermi level in the proximity of the heterojunction interface between the electron transit layer 23 and the electron supply layer 24. Thus, a two-dimensional electron gas (2DEG) 25 spreads in the electron transit layer 23 at a position proximate to the heterojunction interface of the electron transit layer 23 and the electron supply layer 24 (e.g., distanced by approximately a few nanometers from interface).

### Configuration of the Cell Region

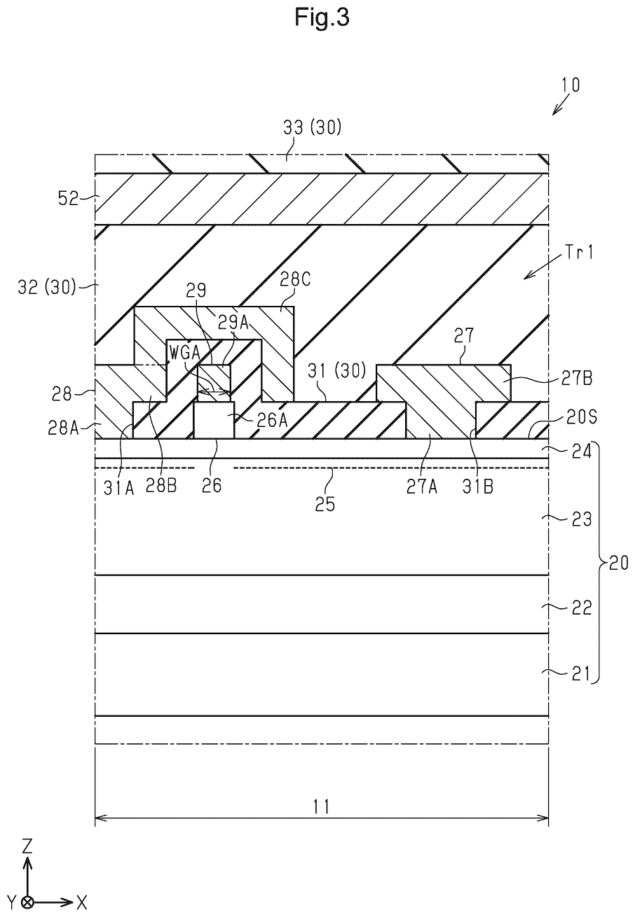

With reference to FIGS. 3 to 5, the configuration of the cell region 11 will now be described.

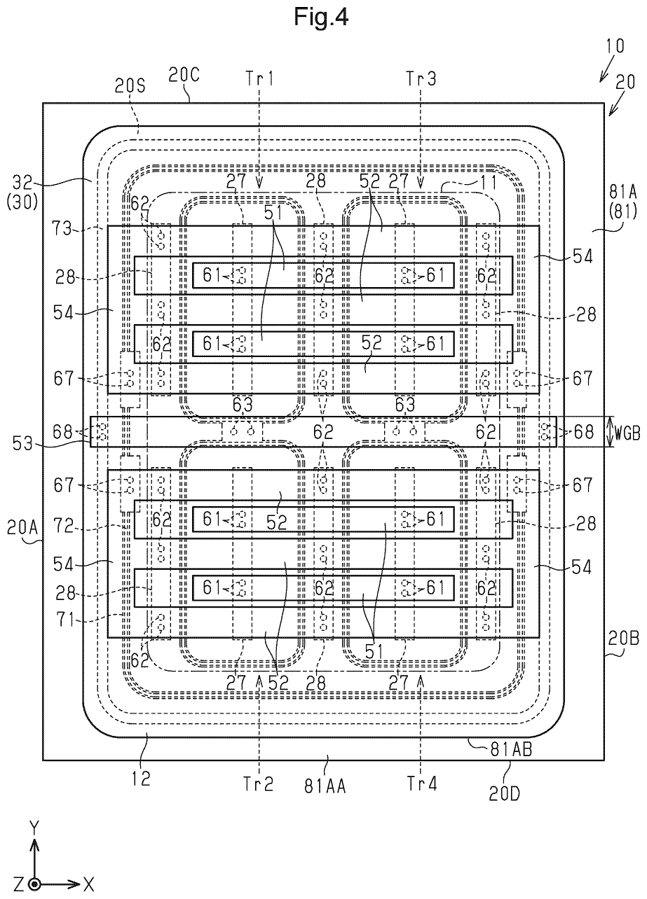

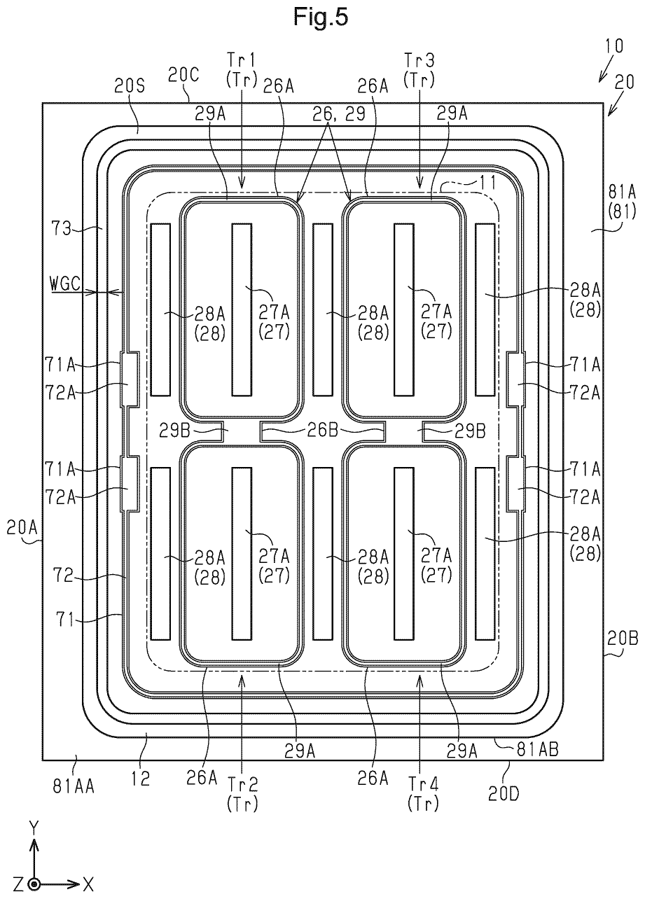

FIG. 3 is an enlarged, schematic cross-sectional view showing part of the cell region 11 in the nitride semiconductor device 10 illustrated in FIG. 2. FIG. 4 is a schematic plan view showing the nitride semiconductor device 10 of FIG. 1 without the drain pad 41, the source pad 42, and the gate pads 43. FIG. 5 is a schematic plan view showing the nitride semiconductor device 10 of FIG. 4 without drain wiring 51, source wiring 52, and gate wiring 53, which will be described later.

As shown in FIG. 5, the nitride semiconductor device 10 includes transistor cells Tr in the cell region 11. In the example shown in FIG. 5, the nitride semiconductor device 10 includes four transistor cells Tr1, Tr2, Tr3, and Tr4. In the description hereafter, if the transistor cells Tr1 to Tr4 do not have to be distinguished from one another, they will be simply referred to as the transistor cells Tr. In FIG. 5, to facilitate understanding, the nitride semiconductor device 10 is shown with only four transistor cells Tr. The nitride semiconductor device 10, however, includes tens to thousands of transistor cells Tr to function as a power transistor (electric power switching transistor).

The four transistor cells Tr1 to Tr4 are separated from one another in at least one of the X-direction and the Y-direction. The transistor cells Tr1 and Tr2 are arranged next to each other in the Y-direction, and the transistor cells Tr3 and Tr4 are arranged next to each other in the Y-direction. The transistor cells Tr1 and Tr2 are arranged next to the transistor cells Tr3 and Tr4 in the X-direction. The transistor cells Tr1 to Tr4 have the same configuration. Thus, only the configuration of the transistor cell Tr1 will be described. The configurations of the transistor cells Tr2 to Tr4 will not be described.

As shown in FIG. 3, the nitride semiconductor device 10 (transistor cell Tr1) includes a gate layer 26, a drain electrode 27, a source electrode 28, and a gate electrode 29. In an example, the gate layer 26, the drain electrode 27, the source electrode 28, and the gate electrode 29 are arranged above the first surface 20S of the semiconductor layer 20.

The gate layer 26 is arranged above a part of the electron supply layer 24. The gate layer 26 is in contact with the electron supply layer 24. The gate layer 26 is formed from a nitride semiconductor. In an example, the gate layer 26 has a smaller band gap than the electron supply layer 24 and is formed from a nitride semiconductor including an acceptor impurity. In an example, the gate layer 26 is a GaN (p-type GaN) layer doped with the acceptor impurity. The acceptor impurity may be at least one of magnesium (Mg), zinc (Zn), and C. In an example, the gate layer 26 has an impurity concentration between 1×10¹⁸ cm⁻³ and 1×10¹⁹ cm⁻³, inclusive. In another example, the gate layer 26 has an impurity concentration between 2×10¹⁸ cm⁻³ and 5×10¹⁸ cm⁻³, inclusive. The gate layer 26 may have any impurity concentration.

The gate electrode 29 is located above the gate layer 26. The gate electrode 29 is in contact with the gate layer 26. For example, the gate electrode 29 may be formed from a material that forms a Schottky junction with the gate layer 26. Therefore, the gate electrode 29 and the gate layer 26 form a Schottky junction.

The gate electrode 29 may include one or more metal layers. In an example, the gate electrode 29 may include a first metal layer, which contacts the gate layer 26, and a second metal layer, which is arranged above the first metal layer. The first metal layer may be formed from a material that forms a Schottky junction with the gate layer 26. In an example, the first metal layer includes at least one of TiN, tantalum nitride (TaN), tungsten nitride (WN), TiSiN, TaSiN, WSi, and WSiN. In an example, the first metal layer includes TiN. In an example, the second metal layer includes Ti.

The gate layer 26 and the gate electrode 29 are covered by the insulating layer 30. In an example, the insulating layer 30 includes a first insulating layer 31 that contacts the electron supply layer 24. The first insulating layer 31 covers the gate layer 26 and the gate electrode 29. For example, the first insulating layer 31 is a passivation layer. For example, the first insulating layer 31 may be formed from one of SiO₂, SiN, silicon oxynitride (SiON), alumina (Al₂O₃), AlN, and aluminum oxynitride (AlON) or by any combination of these compositions. The first insulating layer 31 includes a source opening 31A and a drain opening 31B, each exposing a part of the upper surface of the electron supply layer 24 (first surface 20S of semiconductor layer 20). The source opening 31A is separated from the drain opening 31B in the X-direction.

The drain electrode 27 contacts the electron supply layer 24 through the drain opening 31B. The source electrode 28 contacts the electron supply layer 24 through the source opening 31A. In this manner, the drain electrode 27 and the source electrode 28 are located above the electron supply layer 24. The drain electrode 27 is separated from the source electrode 28 in the X-direction. The gate electrode 29 and the gate layer 26 are both located between the drain electrode 27 and the source electrode 28 in the X-direction. The drain electrode 27 and the source electrode 28 are both in ohmic contact with the electron supply layer 24 (2DEG 25).

The drain electrode 27 includes a drain contact 27A, arranged in the drain opening 31B, and a drain flange 27B, arranged above the first insulating layer 31. For example, the drain contact 27A is integrated with the drain flange 27B. The drain contact 27A is in contact with the electron supply layer 24.

The source electrode 28 includes a source contact 28A, arranged in the source opening 31A, and a source flange 28B, arranged above the first insulating layer 31. For example, the source electrode 28 may include a source field plate 28C. For example, the source contact 28A, the source flange 28B, and the source field plate 28C are integrated with one another. The source contact 28A is in contact with the electron supply layer 24. For example, the source field plate 28C is arranged above the first insulating layer 31. For example, the source field plate 28C extends from the source flange 28B toward the drain electrode 27 in plan view so as to cover both the gate electrode 29 and the gate layer 26. The source field plate 28C is separated from the drain electrode 27 in the X-direction. In an example, the boundary between the source field plate 28C and the source flange 28B is indicated by the double-dashed line.

The drain electrode 27 and the source electrode 28 each include one or more metal layers. In an example, the drain electrode 27 and the source electrode 28 may be formed from one of Ti, TiN, Al, aluminum silicon copper (AlSiCu), and aluminum copper (AlCu) or any combination of such materials. In an example, the drain electrode 27 and the source electrode 28 each include a first metal layer contacting the electron supply layer 24, a second metal layer formed on the first metal layer, a third metal layer formed on the second metal layer, and a fourth metal layer formed on the third metal layer. For example, the first metal layer is a Ti layer, the second metal layer is an Al layer, the third metal layer is a Ti layer, and the fourth metal layer is a TiN layer.

As shown in FIG. 5, the drain contact 27A of the drain electrode 27 and the source contact 28A of the source electrode 28 are both strip-shaped in plan view and both extend in the Y-direction. The drain electrode 27 is one of a plurality of drain electrodes 27, and the source electrode 28 is one of a plurality of source electrodes 28. The drain electrodes 27 and the source electrodes 28 are arranged in correspondence with the transistor cells Tr1 to Tr4. The drain electrode 27 and the source electrode 28 corresponding to the transistor cell Tr1 are separated from the drain electrode 27 and the source electrode 28 corresponding to the transistor cell Tr3 in the X-direction. The drain electrode 27 and the source electrode 28 corresponding to the transistor cell Tr2 are separated from the drain electrode 27 and the source electrode 28 corresponding to the transistor cell Tr4 in the X-direction. The drain electrodes 27 and the source electrodes 28 corresponding to the transistor cells Tr1 and Tr3 are separated from the drain electrodes 27 and the source electrodes 28 corresponding to the transistor cells Tr2 and Tr4 in the Y-direction. The source electrodes 28 may each be integrated with the source field plate 28C (refer to FIG. 3). In this case, there may be only one source electrode 28.

The gate layer 26 and the gate electrode 29 are both looped and surround the drain electrode 27 in plan view. The term “looped” as used in this specification may refer to an endless and continuous looped shape, or to a generally looped shape having a gap, such as a shape similar to the letter C. A “looped” shape includes, but is not limited to, a circular shape, an elliptical shape, and a polygonal shape with acute or rounded corners. In the nitride semiconductor device 10 of an example, the transistor cells Tr1 and Tr2 share the gate layer 26 and the gate electrode 29, and the transistor cells Tr3 and Tr4 share the gate layer 26 and the gate electrode 29. The gate layer 26 and the gate electrode 29 are both located at a position adjacent to the source electrode 28 in the X-direction. As shown in FIG. 3, the gate layer 26 and the gate electrode 29 are both located closer to the source opening 31A than to the drain opening 31B in the X-direction.

As shown in FIG. 5, the gate layer 26 includes a looped portion 26A and a connecting portion 26B, and the gate electrode 29 includes a looped portion 29A and a connecting portion 29B.

The looped portions 26A and 29A are arranged in correspondence with the transistor cells Tr1 to Tr4. More specifically, the gate layer 26 and the gate electrode 29 in each of the transistor cells Tr1 to Tr4 include a looped portion 26A and a looped portion 29A, respectively.

The connecting portion 26B connects the looped portions 26A that are adjacent in the Y-direction, and the connecting portions 29B connect the looped portions 29A that are adjacent in the Y-direction. Therefore, in the example shown in FIG. 5, there are two connecting portions 26B and two connecting portions 29B. More specifically, one connecting portion 26B connects the looped portion 26A of the transistor cell Tr1 to the looped portion 26A of the transistor cell Tr2. The other connecting portion 26B connects the looped portion 26A of the transistor cell Tr3 to the looped portion 26A of the transistor cell Tr4. One connecting portion 29B connects the looped portion 29A of the transistor cell Tr1 to the looped portion 29A of the transistor cell Tr2. The other connecting portion 29B connects the looped portion 29A of the transistor cell Tr3 to the looped portion 29A of the transistor cell Tr4. The sets of the connecting portions 26B and 29B are separated from each other in the X-direction in plan view.

As shown in FIG. 3, the drain electrode 27 and the source electrode 28 are both covered by the insulating layer 30. In an example, the insulating layer 30 includes a second insulating layer 32 covering the drain electrode 27 and the source electrode 28. The second insulating layer 32 is arranged above the first insulating layer 31. For example, the second insulating layer 32 is an interlayer film. For example, the second insulating layer 32 may be formed from SiO₂.

In a structure in which the gate layer 26 is formed from a nitride semiconductor including an acceptor impurity, the 2DEG 25 is depleted in the region underneath the gate layer 26 to interrupt the conduction path (channel) in a zero bias state in which voltage is not applied to the gate electrode 29. Therefore, the HEMT is of a normally-off type of which the gate threshold voltage is a positive value. The application of an appropriate voltage (on-voltage) to the gate electrode 29 will form a channel with the 2DEG 25 in a region of the electron transit layer 23 underneath the gate layer 26 and electrically connect the source and drain.

As shown in FIG. 4, the nitride semiconductor device 10 includes the drain wiring 51, the source wiring 52, and the gate wiring 53 that are electrically connected to the transistor cells Tr1 to Tr4. The drain wiring 51, the source wiring 52, and the gate wiring 53 are arranged above the first surface 20S of the semiconductor layer 20. The drain wiring 51, the source wiring 52, and the gate wiring 53 are each embedded in the insulating layer 30. In an example, the drain wiring 51, the source wiring 52, and the gate wiring 53 are each arranged above the second insulating layer 32. In FIG. 4, parts of the insulating layer 30 are not shown for the sake of simplicity.

As shown in FIGS. 3 and 4, the insulating layer 30 includes a third insulating layer 33 covering each of the drain wiring 51, the source wiring 52, and the gate wiring 53. Therefore, the drain wiring 51, the source wiring 52, and the gate wiring 53 are each sandwiched between the second insulating layer 32 and the third insulating layer 33. In an example, the drain wiring 51, the source wiring 52, and the gate wiring 53 are located at the same position in the Z-direction.

As shown in FIG. 4, the drain wiring 51 is one of a plurality of drain wirings 51, and the source wiring 52 is one of a plurality of source wirings 52. The drain wirings 51 and the source wirings 52 are arranged alternately one after another in the Y-direction. The drain wirings 51 and the source wirings 52 are each strip-shaped in plan view and extend in the X-direction. The source wirings 52 are longer in the X-direction than the drain wirings 51. In an example, the drain wirings 51 are arranged in the cell region 11 but not arranged in the peripheral region 12. Each source wiring 52 extends in the X-direction through the cell region 11 into the peripheral region 12. The source wirings 52 are connected to one another by source connecting wirings 54. The source connecting wirings 54 are located at the two X-direction ends of each of the source wirings 52. Therefore, two source connecting wirings 54 are located in the peripheral region 12. The transistor cells Tr1 and Tr3 share the same drain wirings 51 and source wirings 52, and the transistor cells Tr2 and Tr4 share the same drain wirings 51 and source wirings 52. In other words, the drain wirings 51 and the source wirings 52 of the transistor cells Tr1 and Tr3 differ from the drain wirings 51 and the source wirings 52 of the transistor cells Tr2 and Tr4.

The gate wiring 53 is shared by the transistor cells Tr1 to Tr4. The gate wiring 53 is located, in the Y-direction, between the transistor cell Tr1 and the transistor cell Tr2 and between the transistor cell Tr3 and the transistor cell Tr4. The gate wiring 53 is strip-shaped and extends in the X-direction in plan view. The gate wiring 53 extends in the X-direction through the cell region 11 into the peripheral region 12. The gate wiring 53 is longer in the X-direction than the source wirings 52. In an example, a width WGB of the gate wiring 53 is greater than a width WGA of the gate electrode 29 (refer to FIG. 3). The width WGA of the gate electrode 29 is the dimension taken in a direction orthogonal to the direction in which the looped portion 29A of the gate electrode 29 extends in plan view. The width WGB of the gate wiring 53 is the dimension taken in a direction (Y-direction in FIG. 4) orthogonal to the direction in which the gate wiring 53 extends (X-direction in FIG. 4) in plan view.

The drain wirings 51, the source wirings 52, the gate wiring 53, and the source connecting wirings 54 may be formed from one of Ti, TiN, Al, AlSiCu, and AlCu or any combination of such materials. In an example, the drain wirings 51, the source wirings 52, the gate wiring 53, and the source connecting wirings 54 may be formed from the same material.

The drain wirings 51 are each electrically connected by drain vias 61 to the drain electrode 27. The source wirings 52 are each electrically connected by source vias 62 to the source electrode 28. The gate wiring 53 is electrically connected by gate vias 63 to the gate electrode 29. The drain vias 61, the source vias 62, and the gate vias 63 each extend through the second insulating layer 32 in the Z-direction. The drain vias 61, the source vias 62, and the gate vias 63 may be formed by a material including at least one of Ti, TiN, Au, Ag, Cu, Al, and W.

The drain pad 41, the source pad 42, and the gate pads 43 shown in FIG. 1 are arranged above the third insulating layer 33 (refer to FIG. 2). The drain pad 41, the source pad 42, and the gate pad 43 are partially covered by a protective layer 34. The protective layer 34 includes a first opening exposing the drain pad 41, a second opening exposing the source pad 42, and third openings exposing the gate pads 43. In an example, the protective layer 34 is formed by a stack of inorganic and organic insulating films. The inorganic insulating film may include, for example, at least one of SiO₂, SiN, and SiON. The organic insulating film may include, for example, a photosensitive resin. One example of a photosensitive resin is polyimide (PI).

As shown in FIG. 1, the nitride semiconductor device 10 includes a drain pad via 64, a source pad via 65, and a gate pad via 66. The drain pad via 64 and the source pad via 65 are both arranged in the cell region 11. The gate pad via 66 is arranged in the peripheral region 12. The drain pad via 64 is separated from the source pad via 65 in the X-direction.

The drain pad via 64 connects one of the drain wirings 51 to the drain pad 41. The drain pad via 64 is one of a plurality of drain pad vias 64 arranged in correspondence with each of the drain wirings 51. In an example, a plurality of drain pad vias 64 are provided for each drain wiring 51.

The source pad via 65 connects one of the source wirings 52 to the source pad 42. The source pad via 65 is one of a plurality of source pad vias 65 arranged in correspondence with each of the source wirings 52. In an example, a plurality of source pad vias 65 are provided for each of the source wirings 52.

The gate pad via 66 connects the gate wiring 53 to one of the gate pads 43. The gate pad via 66 is one of a plurality of gate pad vias 66 arranged in correspondence with each of the gate pads 43. In an example, a plurality of gate pad vias 66 are provided for each of the gate pads 43.

The drain pad vias 64, the source pad vias 65, and the gate pad vias 66 may be formed from a material including at least one of Ti, TiN, Au, Ag, Cu, Al, and W. The drain pad vias 64, the source pad vias 65, and the gate pad vias 66 may be formed from the same conductive material. The drain pad vias 64, the source pad vias 65, and the gate pad vias 66 may be formed from the same conductive material as the drain vias 61, the source vias 62, and the gate vias 63. There is no limitation to the number of the drain pad vias 64, the source pad vias 65, and the gate pad vias 66.

### Configuration of the Peripheral Region

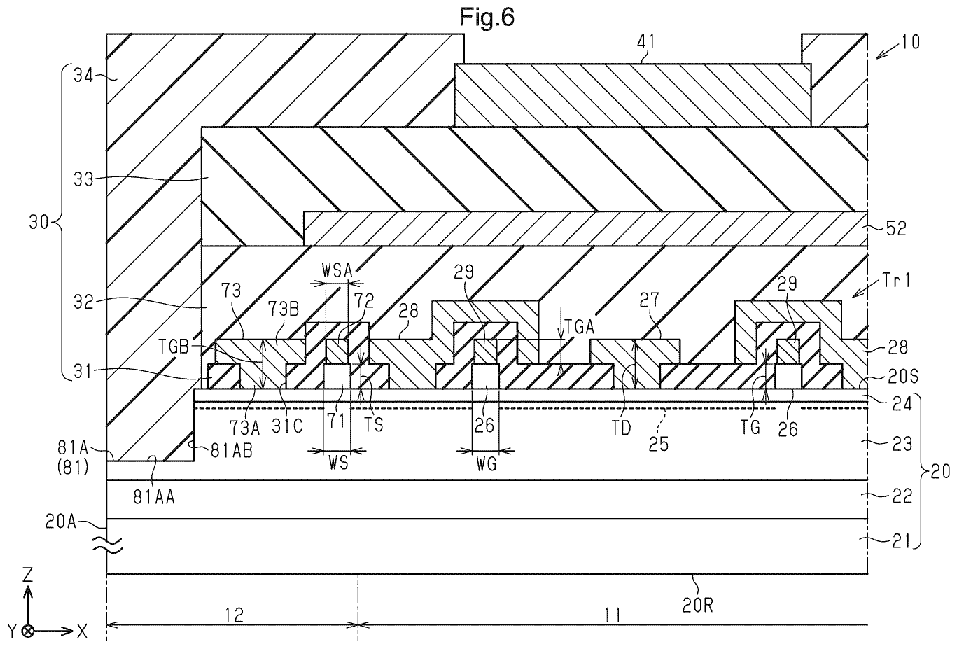

With reference to FIGS. 4 to 6, the configuration of the peripheral region 12 will now be described. FIG. 6 is an enlarged, schematic cross-sectional view showing the peripheral region 12 of the nitride semiconductor device 10 illustrated in FIG. 2.

As shown in FIG. 6, in the peripheral region 12, the nitride semiconductor device 10 includes a nitride semiconductor layer 71, a first peripheral electrode 73, and a second peripheral electrode 72, which is located above the nitride semiconductor layer 71. In the first embodiment, the nitride semiconductor layer 71 and the first peripheral electrode 73 are both located above the electron supply layer 24. In an example, the nitride semiconductor layer 71 and the first peripheral electrode 73 are both in contact with the electron supply layer 24. The first peripheral electrode 73 is in ohmic contact with the electron supply layer 24 (2DEG 25). In an example, the first peripheral electrode 73 and the drain electrode 27 are located at the same position in the Z-direction. Further, the nitride semiconductor layer 71 and the first peripheral electrode 73 are located at the same position as the gate layer 26 in the Z-direction. The nitride semiconductor layer 71 is separated from the first peripheral electrode 73 in the X-direction. In the first embodiment, the nitride semiconductor layer 71 is located closer to the cell region 11 than the first peripheral electrode 73 is in plan view. In an example, the nitride semiconductor layer 71 is located closer to the first peripheral electrode 73 than the one of the gate layers 26 in the cell region 11 closest to the peripheral region 12 is in the X-direction. In other words, the distance between the nitride semiconductor layer 71 and the first peripheral electrode 73 in the X-direction is shorter than the distance between the nitride semiconductor layer 71 and the gate layer 26 in the X-direction.

The nitride semiconductor layer 71 is formed from a nitride semiconductor. In an example, the nitride semiconductor layer 71 has a smaller band gap than the electron supply layer 24 and is formed from a nitride semiconductor including an acceptor impurity. In an example, the nitride semiconductor layer 71 is a GaN (p-type GaN) layer doped with the acceptor impurity. The acceptor impurity may be at least one of Mg, Zn, and C. In an example, the nitride semiconductor layer 71 has an impurity concentration between 1×10¹⁸ cm⁻³ and 1×10¹⁹ cm⁻³, inclusive. Further, in an example, the nitride semiconductor layer 71 has an impurity concentration between 2×10¹⁸ cm⁻³ and 5×10¹⁸ cm⁻³, inclusive. In an example, the nitride semiconductor layer 71 and the gate layer 26 may be equal in impurity concentration. The nitride semiconductor layer 71 may have any impurity concentration. In an example, the impurity concentration of the nitride semiconductor layer 71 may differ from that of the gate layer 26.

The nitride semiconductor layer 71 is electrically connected to the transistors (transistor cells Tr1 to Tr4) in the cell region 11 by the 2DEG 25. A thickness TS of the nitride semiconductor layer 71 may be equal to a thickness TG of the gate layer 26. In an example, a width WS of the nitride semiconductor layer 71 is equal to a width WG of the gate layer 26. The nitride semiconductor layer 71 may have any width WS. In an example, the width WS of the nitride semiconductor layer 71 may be less than the width WG of the gate layer 26. In another example, the width WS of the nitride semiconductor layer 71 may be greater than the width WG of the gate layer 26.

As shown in FIG. 5, the nitride semiconductor layer 71 is looped in plan view. In an example, the nitride semiconductor layer 71 has the shape of a quadrilateral loop in plan view. In an example, the four corners of the nitride semiconductor layer 71, which has the shape of a quadrilateral loop, are curved outward. The nitride semiconductor layer 71 surrounds the cell region 11 in plan view.

The second peripheral electrode 72, which is located above the looped nitride semiconductor layer 71, is looped in plan view. In an example, the second peripheral electrode 72 has the shape of a quadrilateral loop in plan view. In an example, the four corners of the second peripheral electrode 72, which has the shape of a quadrilateral loop, are curved outward. The second peripheral electrode 72 surrounds the cell region 11 in plan view.

As shown in FIG. 6, a width WSA of the second peripheral electrode 72 is equal to the width WGA of the gate electrode 29. The width WSA of the second peripheral electrode 72 is the width of the portion of the second peripheral electrode 72 excluding a widened portion 72A, which will be described later. The second peripheral electrode 72 may have any width WSA. In an example, the width WSA of the second peripheral electrode 72 may be less than the width WGA of the gate electrode 29. In another example, the width WSA of the second peripheral electrode 72 may be greater than the width WGA of the gate electrode 29.

The second peripheral electrode 72 is in contact with the nitride semiconductor layer 71. The second peripheral electrode 72 may be formed from, for example, a material that forms a Schottky junction with the nitride semiconductor layer 71. Therefore, the second peripheral electrode 72 and the nitride semiconductor layer 71 form a Schottky junction.

The second peripheral electrode 72 may include one or more metal layers. In an example, the second peripheral electrode 72 may include a first metal layer, which contacts the nitride semiconductor layer 71, and a second metal layer, which is arranged above the first metal layer. The first metal layer may be formed from a material that forms a Schottky junction with the nitride semiconductor layer 71. In an example, the first metal layer includes at least one of TiN, TaN, WN, TiSiN, TaSiN, WSi, and WSiN. In an example, the first metal layer includes TiN. In an example, the second metal layer includes Ti. In this manner, the second peripheral electrode 72 and the gate electrode 29 are formed from the same conductive material.

As shown in FIG. 5, the nitride semiconductor layer 71 includes a widened portion 71A, and the second peripheral electrode 72 includes the widened portion 72A. The widened portion 71A of the nitride semiconductor layer 71 has a greater width than the portion of the nitride semiconductor layer 71 excluding the widened portion 71A. The widened portion 72A of the second peripheral electrode 72 has a greater width than the portion of the second peripheral electrode 72 excluding the widened portion 72A. The widened portion 71A of the nitride semiconductor layer 71 overlaps the widened portion 72A of the second peripheral electrode 72 in plan view. As shown in FIG. 5, the widened portion 71A is one of a plurality of (four) widened portions, and the widened portion 72A is one of a plurality of (four) widened portions 72A. There is no limitation to the number of the widened portions 71A and 72A.

Some of the widened portions 71A and 72A are located closer to the first side surface 20A of the semiconductor layer 20 than the transistor cells Tr1 and Tr2 are. These widened portions 71A and 72A are separated from each other in the Y-direction in plan view. The other widened portions 71A and 72A are located closer to the second side surface 20B of the semiconductor layer 20 than the transistor cells Tr3 and Tr4 are. These widened portions 71A and 72A are separated from each other in the Y-direction in plan view.

The first peripheral electrode 73 is looped and surrounds the nitride semiconductor layer 71 and the second peripheral electrode 72 in plan view. In an example, the first peripheral electrode 73 has the shape of a quadrilateral loop in plan view. In an example, the four corners of the first peripheral electrode 73, which has the shape of a quadrilateral loop, are curved outward. In the example shown in FIG. 5, the width WGC of the first peripheral electrode 73 is greater than the width WGA of the gate electrode 29 (refer to FIG. 3). The width WGC of the first peripheral electrode 73 is greater than the width WSA of the second peripheral electrode 72 (refer to FIG. 6). The width WGC of the first peripheral electrode 73 is the dimension in the direction orthogonal to the direction in which the first peripheral electrode 73 extends in plan view. The width WSA of the second peripheral electrode 72 (refer to FIG. 6) is the dimension in the direction orthogonal to the direction in which the second peripheral electrode 72 extends in plan view. In an example, the width WGC of the first peripheral electrode 73 is greater than the width WS of the nitride semiconductor layer 71.

In an example, the total length of the first peripheral electrode 73 is between 1% and 40%, inclusive, of the total length of the gate electrodes 29. In an example, the total length of the first peripheral electrode 73 is between 5% and 20%, inclusive, of the total length of the gate electrodes 29. In an example, the total length of the first peripheral electrode 73 may be between 10% and 15%, inclusive, of the total length of the gate electrodes 29. The total length of the first peripheral electrode 73 may be defined as the perimeter of the first peripheral electrode 73, which has the shape of a quadrilateral loop, in plan view. The total length of the gate electrodes 29 may be defined as the total perimeter of the looped portions 29A in plan view. In the example shown in FIG. 5, the gate electrodes 29 include four looped portions 29A. Thus, the total length of the gate electrodes 29 is four times the perimeter of a single looped portion 29A. There is no limitation to the relationship between the total length of the first peripheral electrode 73 and the total length of the gate electrodes 29.

The first peripheral electrode 73 may be formed from one of Ti, TiN, Al, aluminum silicon copper, and aluminum copper or any combination of such materials. In an example, the first peripheral electrode 73 includes a first metal layer, which contacts the electron supply layer 24, a second metal layer, which is formed on the first metal layer, a third metal layer, which is formed on the second metal layer, and a fourth metal layer, which is formed on the third metal layer. For example, the first metal layer is a Ti layer, the second metal layer is an Al layer, the third metal layer is a Ti layer, and the fourth metal layer is a TiN layer. For example, the first peripheral electrode 73 may be formed from the same conductive material as the drain electrode 27 and the source electrode 28.

As shown in FIG. 6, the nitride semiconductor layer 71 and the second peripheral electrode 72 are covered by the insulating layer 30. In an example, the nitride semiconductor layer 71 and the second peripheral electrode 72 are covered by the first insulating layer 31. The first insulating layer 31 includes a peripheral opening 31C. The peripheral opening 31C is arranged in the peripheral region 12. The peripheral opening 31C is looped and surrounds the nitride semiconductor layer 71 and the second peripheral electrode 72 in plan view. The first peripheral electrode 73 contacts the electron supply layer 24 through the peripheral opening 31C. The first peripheral electrode 73 includes a portion located above the first insulating layer 31. In this manner, the first peripheral electrode 73 includes a contact portion 73A, which contacts the electron supply layer 24, and a flange portion 73B, which is located above the first insulating layer 31. The contact portion 73A is integrated with the flange portion 73B. In an example, the thickness TGB of the first peripheral electrode 73 is greater than the thickness TGA of the gate electrode 29. In an example, the thickness TGB of the first peripheral electrode 73 is greater than the thickness TS of the nitride semiconductor layer 71. In an example, the thickness TGB of the first peripheral electrode 73 is greater than the thickness TG of the gate layer 26. In an example, the thickness TGB of the first peripheral electrode 73 is equal to a thickness TD of the drain electrode 27.

The nitride semiconductor device 10 includes a peripheral isolation region 81 located in a region including the edges of the peripheral region 12. The edges of the peripheral region 12 overlap the first to fourth side surfaces 20A to 20D of the semiconductor layer 20 in plan view. The peripheral isolation region 81 includes a recess 81A extending through the electron supply layer 24 and at least part of the electron transit layer 23 in the Z-direction. Therefore, in the peripheral isolation region 81, the electron supply layer 24 is removed from the semiconductor layer 20. In the example shown in FIG. 6, part of the electron transit layer 23 is removed in the Z-direction in the peripheral isolation region 81. In an example, at least the portion of the electron transit layer 23 where the 2DEG 25 is formed in the Z-direction is removed in the peripheral isolation region 81. In the example shown in FIG. 6, the peripheral isolation region 81 is formed by performing etching (e.g., mesa etching) to remove part of the electron transit layer 23 and the electron supply layer 24 in the Z-direction.

The recess 81A of the peripheral isolation region 81 includes a bottom surface 81AA, which is defined by the upper surface of the electron transit layer 23, and side surfaces 81AB, which are defined by the side surfaces of the electron transit layer 23 and the side surfaces of the electron supply layer 24. The side surfaces 81AB are located toward the inner side of the semiconductor layer 20 from the first to fourth side surfaces 20A to 20D of the semiconductor layer 20 in plan view.

As shown in FIG. 5, the peripheral isolation region 81 is looped and surrounds the first peripheral electrode 73 in plan view. In an example, the peripheral isolation region 81 is separated from the first peripheral electrode 73 toward the edges of the peripheral region 12 in plan view. In an example, the peripheral isolation region 81 has the shape of a quadrilateral loop in plan view. The four corners in the inner edges of the peripheral isolation region 81 are curved outward in correspondence with the shape of the first peripheral electrode 73 in plan view.

As shown in FIG. 6, the peripheral isolation region 81 is covered by the protective layer 34. Therefore, the protective layer 34 covers the bottom surface 81AA and the side surfaces 81AB exposed from the recess 81A of the peripheral isolation region 81. Further, the protective layer 34 covers the side surfaces of the first to third insulating layers 31 to 34.

### Electrical Connection Structure

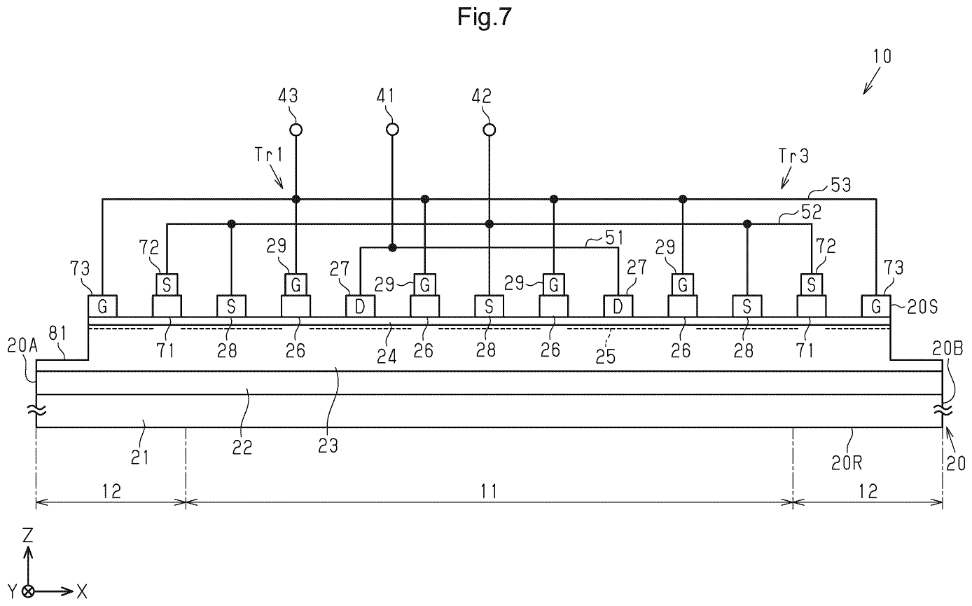

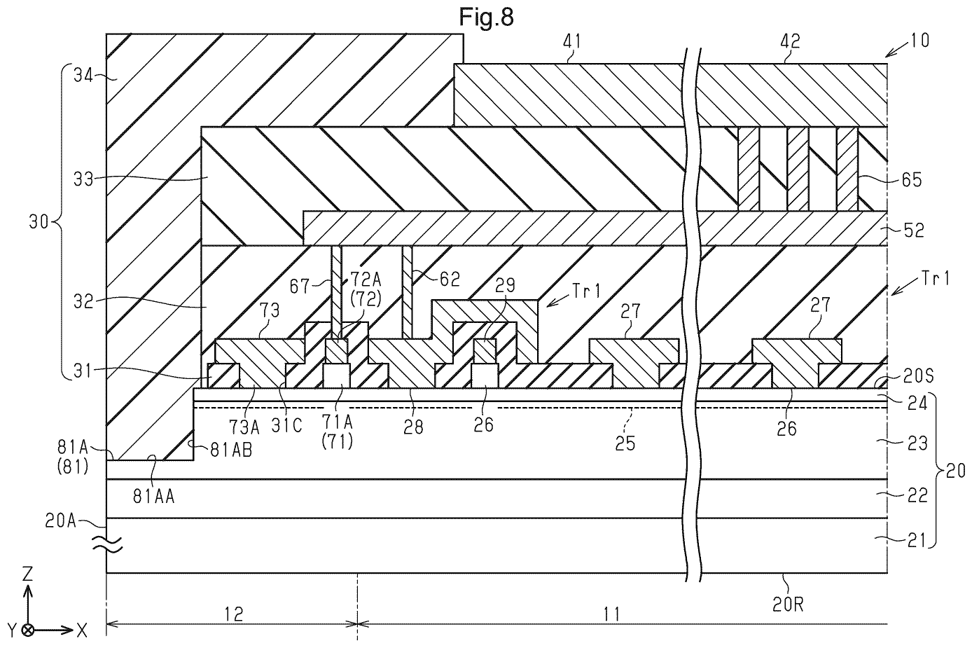

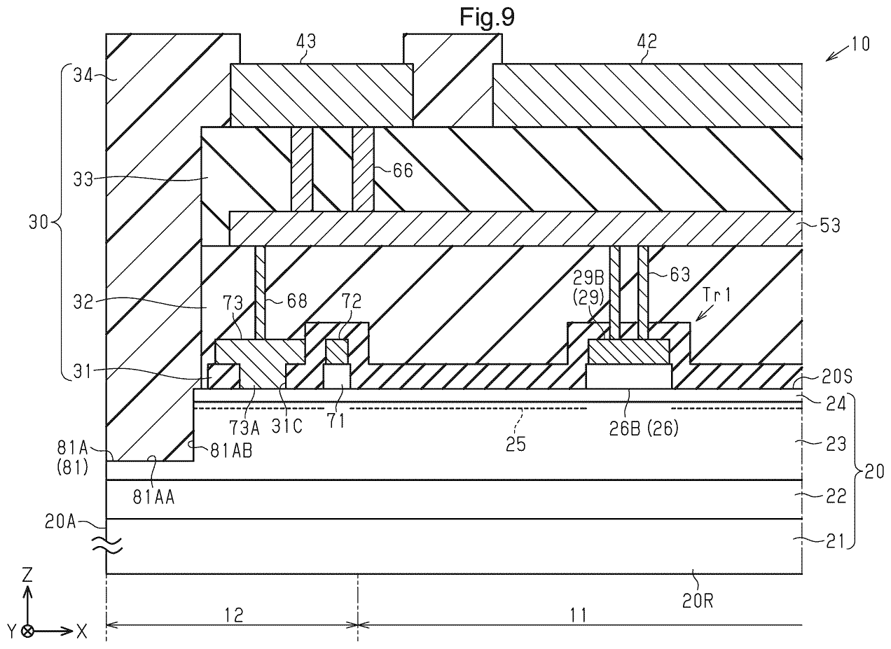

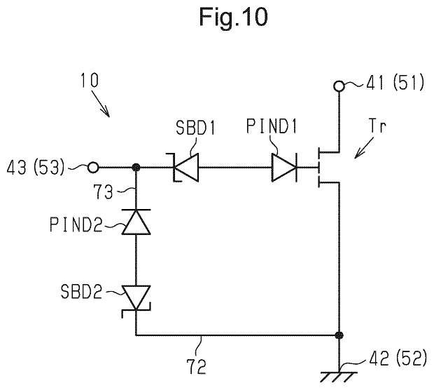

With reference to FIGS. 7 to 10, the electrical connection structure of the nitride semiconductor device 10 will now be described. FIG. 7 schematically shows the electrical connection structure of the nitride semiconductor device 10. FIG. 8 is a schematic cross-sectional view of the nitride semiconductor device 10 taken along line F8-F8 in FIG. 1, and shows the structure connecting the source electrode 28, the source wiring 52, and the source pad 42. FIG. 9 is a schematic cross-sectional view of the nitride semiconductor device 10 taken along line F9-F9 in FIG. 1, and shows the structure connecting the gate electrode 29, the gate wiring 53, and the gate pad 43. FIG. 10 is a schematic circuit diagram of the nitride semiconductor device 10.

As shown in FIG. 7, the drain electrodes 27 are connected to one another by the drain wiring 51. Further, the drain electrodes 27 are connected by the drain wiring 51 to the drain pad 41.

The source electrodes 28 are connected to one another by the source wiring 52. The source electrodes 28 are electrically connected to the second peripheral electrode 72. In an example, the source electrodes 28 are electrically connected by the source wiring 52 to the second peripheral electrode 72. The source electrodes 28 and the second peripheral electrode 72 are electrically connected by the source wiring 52 to the source pad 42.

Accordingly, the second peripheral electrode 72 is in a state similar to zero-bias in which voltage is not applied to the gate electrodes 29 in the cell region 11. Therefore, in the nitride semiconductor layer 71 formed by the nitride semiconductor including an acceptor impurity, the 2DEG 25 is depleted in the region underneath the nitride semiconductor layer 71. This isolates the 2DEG 25 of the cell region 11 from the 2DEG 25 of the peripheral region 12.

The gate electrodes 29 are electrically connected to one another by the gate wiring 53. The gate electrodes 29 are electrically connected to the first peripheral electrode 73. In an example, the gate electrodes 29 are electrically connected by the gate wiring 53 to the first peripheral electrode 73. The gate electrodes 29 and the first peripheral electrode 73 are electrically connected by the gate wiring 53 to the gate pad 43.

As shown in FIGS. 8 and 9, the nitride semiconductor device 10 includes second peripheral vias 67 and first peripheral vias 68. The second peripheral vias 67 and the first peripheral vias 68 are both arranged in the peripheral region 12. The second peripheral vias 67 connect the source wiring 52 and the second peripheral electrode 72. The first peripheral vias 68 connect the gate wiring 53 and the first peripheral electrode 73. The second peripheral vias 67 extend through both the first insulating layer 31 and the second insulating layer 32 in the Z-direction. The first peripheral vias 68 extend through the second insulating layer 32 in the Z-direction. The second peripheral vias 67 and the first peripheral vias 68 may be formed from a material including at least one of Ti, TiN, Au, Ag, Cu, Al, and W. The second peripheral vias 67 and the first peripheral vias 68 may be formed from the same conductive material. The second peripheral vias 67 and the first peripheral vias 68 may be formed from the same conductive material as the drain vias 61, the source vias 62, and the gate vias 63.

As shown in FIG. 10, the electrical connection structure of the nitride semiconductor device 10 includes the transistor (transistor cell Tr) of the nitride semiconductor device 10, a first Schottky barrier diode SBD1, a first PIN diode PIND1, a second Schottky barrier diode SBD2, and a second PIN diode PIND2.

The first Schottky barrier diode SBD1 is formed by the Schottky junction of the gate electrode 29 and the gate layer 26 (refer to FIG. 9). The first PIN diode PIND1 is formed by the gate layer 26, the electron supply layer 24, and the electron transit layer 23 (refer to FIG. 9). Therefore, the anode of the first Schottky barrier diode SBD1 is electrically connected to the anode of the first PIN diode PIND1 by the gate layer 26. The cathode of the first Schottky barrier diode SBD1 is electrically connected to the gate pad 43 (gate wiring 53). The cathode of the first PIN diode PIND1 is electrically connected to the 2DEG 25.

The second Schottky barrier diode SBD2 is formed by the Schottky junction of the second peripheral electrode 72 and the nitride semiconductor layer 71 (refer to FIG. 8). The second PIN diode PIND2 is formed by the electron transit layer 23, the electron supply layer 24, and the nitride semiconductor layer 71. The second Schottky barrier diode SBD2 and the second PIN diode PIND2 are electrically connected by the 2DEG 25 to the first peripheral electrode 73. That is, the second Schottky barrier diode SBD2 and the second PIN diode PIND2 are electrically connected by the first peripheral electrode 73 to the gate electrode 29 (gate pad 43). The cathode of the second Schottky barrier diode SBD2 is electrically connected to the source electrode 28 (source wiring 52). The anode of the second Schottky barrier diode SBD2 is electrically connected to the anode of the second PIN diode PIND2 by the nitride semiconductor layer 71. The cathode of the second PIN diode PIND2 is electrically connected to the first peripheral electrode 73 (gate pad 43).

Method for Manufacturing the Nitride Semiconductor Device

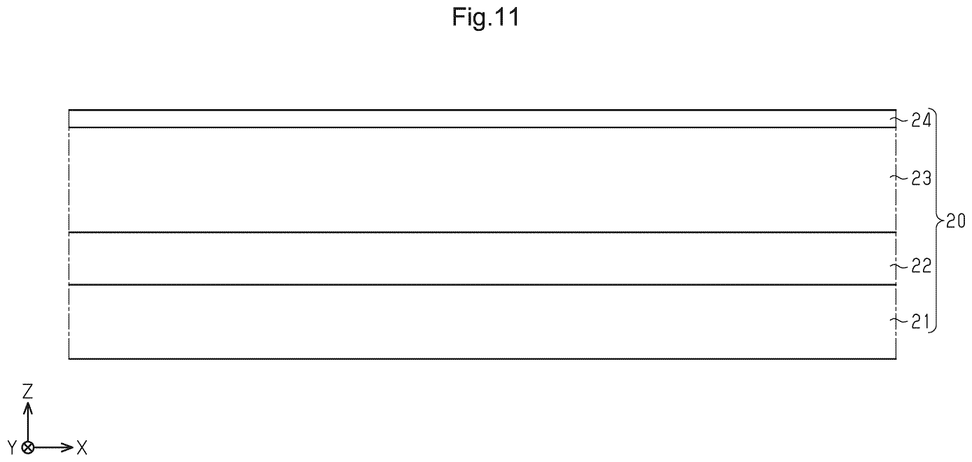

With reference to FIGS. 11 to 16, one example of a method for manufacturing the nitride semiconductor device 10 will now be described. FIGS. 11 to 16 are cross-sectional views showing manufacturing steps of the nitride semiconductor device 10. In the description hereafter, to clarify the relationship with the elements of the nitride semiconductor device 10 described above, the same reference characters are given to those elements that are the same as the corresponding elements.

As shown in FIG. 11, the method for manufacturing the nitride semiconductor device 10 includes forming the semiconductor layer 20. In an example, the method for manufacturing the nitride semiconductor device 10 includes forming the buffer layer 22 above the semiconductor substrate 21, forming the electron transit layer 23 above the semiconductor substrate 21, and forming the electron supply layer 24 above the electron transit layer 23. The electron transit layer 23 is formed above the buffer layer 22.

In an example, the semiconductor substrate 21 is first prepared. For example, a Si substrate is used as the semiconductor substrate 21. Then, the buffer layer 22, the electron transit layer 23, and the electron supply layer 24 are stacked one after another on the semiconductor substrate 21. The buffer layer 22, the electron transit layer 23, and the electron supply layer 24 may be formed by epitaxial growth using metal organic chemical vapor deposition.

Although not shown in detail in the drawings, in an example, the buffer layer 22 may be multilayered. A multilayered buffer layer may include an AlN layer (first buffer layer), formed above the semiconductor substrate 21, and a graded AlGaN layer (second buffer layer), formed on the AlN layer. For example, the graded AlGaN may be formed by stacking three AlGaN layers having Al compositions of 75%, 50%, and 25% in order from the side closer to the AlN layer.

The electron transit layer 23, formed above the buffer layer 22, may be a GaN layer. The electron supply layer 24, formed above the electron transit layer 23, may be an AlGaN layer. The electron supply layer 24 has a larger band gap than the electron transit layer 23.

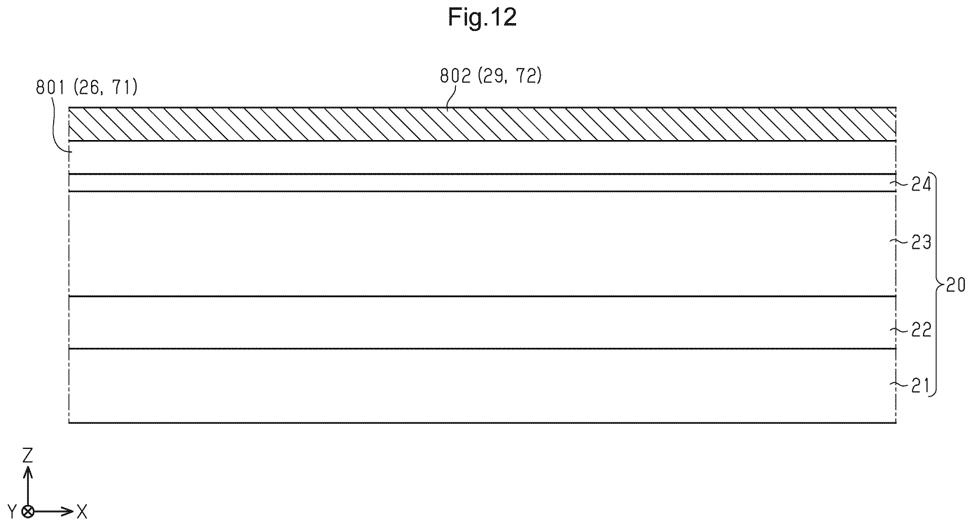

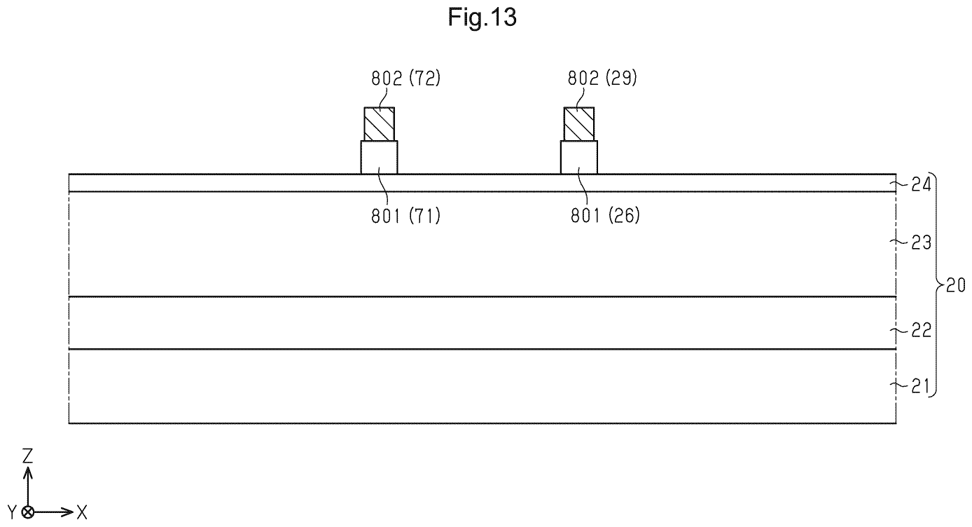

As shown in FIGS. 12 and 13, the method for manufacturing the nitride semiconductor device 10 includes forming the gate layer 26, forming the nitride semiconductor layer 71, forming the gate electrode 29, and forming the second peripheral electrode 72.

In this step, as shown in FIG. 12, a nitride semiconductor layer 801, which forms the gate layer 26 and the nitride semiconductor layer 71, is formed above the electron supply layer 24. In the same manner as the electron supply layer 24 and the like, the nitride semiconductor layer 801 may be formed by epitaxial growth. For example, the nitride semiconductor layer 801 is a GaN layer including an acceptor impurity. The nitride semiconductor layer 801 may be doped with Mg during growth to form the nitride semiconductor layer 801 that includes an acceptor impurity. For example, the amount of Mg with which the nitride semiconductor layer 801 is doped may be adjusted by controlling the growth temperature and the flow rate of the doping gas, such as bis(cyclopentadienyl)magnesium (Cp₂Mg), supplied to the growth chamber. In an example, the nitride semiconductor layer 801 may include, as the impurity, Mg at a concentration between 1×10¹⁸ cm⁻³ and 1×10¹⁹ cm⁻³, inclusive. In a further example, the nitride semiconductor layer 801 may include, as the impurity, Mg at a concentration between 2×10¹⁸ cm⁻³ and 5×10¹⁸ cm⁻³. Subsequent to removal from the growth chamber, a thermal treatment is performed under a nitrogen atmosphere to activate the doped Mg. The thermal treatment dissociates hydrogen that was bonded to Mg. This increases the activating rate of Mg. As a result, a normally-off operation can be performed at a relatively low Mg concentration between 1×10¹⁸ cm⁻³ and 1×10¹⁹ cm⁻³.

An electrode layer 802 is formed on the nitride semiconductor layer 801. The electrode layer 802 may be a stack of a first electrode layer including TiN and a second electrode layer including Ti. As shown in FIG. 13, lithography and etching are performed, using a first mask (not shown), to selectively remove the electrode layer 802. The first mask is formed on the electrode layer 802. The first mask includes openings exposing portions of the electrode layer 802 other than the gate electrode 29 and the second peripheral electrode 72. The portions of the electrode layer 802 exposed from the openings are removed. This forms the gate electrode 29 and the second peripheral electrode 72. Therefore, the gate electrode 29 and the second peripheral electrode 72 are formed in the same step. In this case, the gate electrode 29 and the second peripheral electrode 72 are formed from the same material. The first mask is removed after the gate electrode 29 and the second peripheral electrode 72 are formed.

Then, anisotropic etching is performed, using a second mask (not shown), to selectively remove the nitride semiconductor layer 801. The second mask covers the side surfaces of each of the gate electrode 29 and the second peripheral electrode 72. Portions of the nitride semiconductor layer 801 excluding the gate electrode 29, the second peripheral electrode 72, and the second mask are removed. This forms the gate layer 26 and the nitride semiconductor layer 71. Therefore, the nitride semiconductor layer 71 and the gate layer 26 are formed in the same step. In this case, the nitride semiconductor layer 71 and the gate layer 26 are equal in impurity concentration. The second mask is removed after the nitride semiconductor layer 71 and the gate layer 26 are formed.

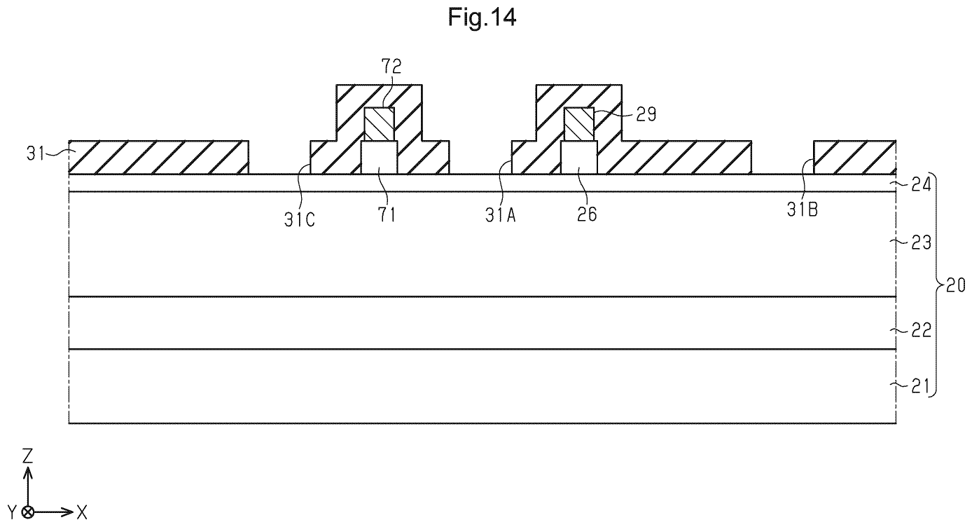

As shown in FIG. 14, the method for manufacturing the nitride semiconductor device 10 includes forming the first insulating layer 31. The first insulating layer 31 may be, for example, a SiN layer. The first insulating layer 31 may be formed by performing, for example, chemical vapor deposition (CVD). Then, lithography and etching, for example, are performed on the first insulating layer 31 to form the drain opening 31B, the source opening 31A, and the peripheral opening 31C.

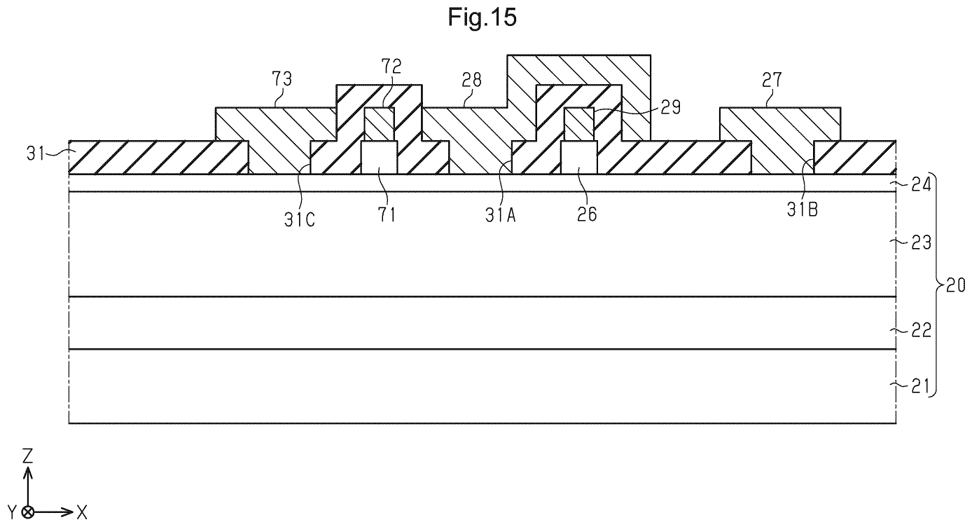

As shown in FIG. 15, the method for manufacturing the nitride semiconductor device 10 includes forming the source electrode 28 and the drain electrode 27, and forming the first peripheral electrode 73.

In this step, a metal layer (not shown) is formed above the first insulating layer 31. In an example, the metal layer includes a first metal layer, which contacts the first insulating layer 31, a second metal layer, which is formed on the first metal layer, a third metal layer, which is formed on the second metal layer, and a fourth metal layer, which is formed on the third metal layer. The first metal layer is, for example, a Ti layer, the second metal layer is, for example, an Al layer, the third metal layer is, for example, a Ti layer, and the fourth metal layer is, for example, a TiN layer. The drain opening 31B, the source opening 31A, and the peripheral opening 31C are each filled with the metal layer. Therefore, the metal layer contacts the electron supply layer 24 through the drain opening 31B, the source opening 31A, and the peripheral opening 31C. Then, lithography and etching are performed using a third mask (not shown) to selectively remove the metal layer. This forms the drain electrode 27, the source electrode 28, and the first peripheral electrode 73. Therefore, the drain electrode 27, the source electrode 28, and the first peripheral electrode 73 are formed in the same step. In this case, the drain electrode 27, the source electrode 28, and the first peripheral electrode 73 are formed from the same material. The third mask is removed after forming the drain electrode 27, the source electrode 28, and the first peripheral electrode 73. Then, a thermal treatment is performed at approximately 550° C. As a result, the drain electrode 27, the source electrode 28, and the first peripheral electrode 73 are brought into ohmic contact with the 2DEG 25, which is in the interface between the electron transit layer 23 and the electron supply layer 24. As long as the drain electrode 27, the source electrode 28, and the first peripheral electrode 73 are brought into ohmic contact with the 2DEG 25, the temperature of the thermal treatment is not limited to approximately 550° C. and may be changed.

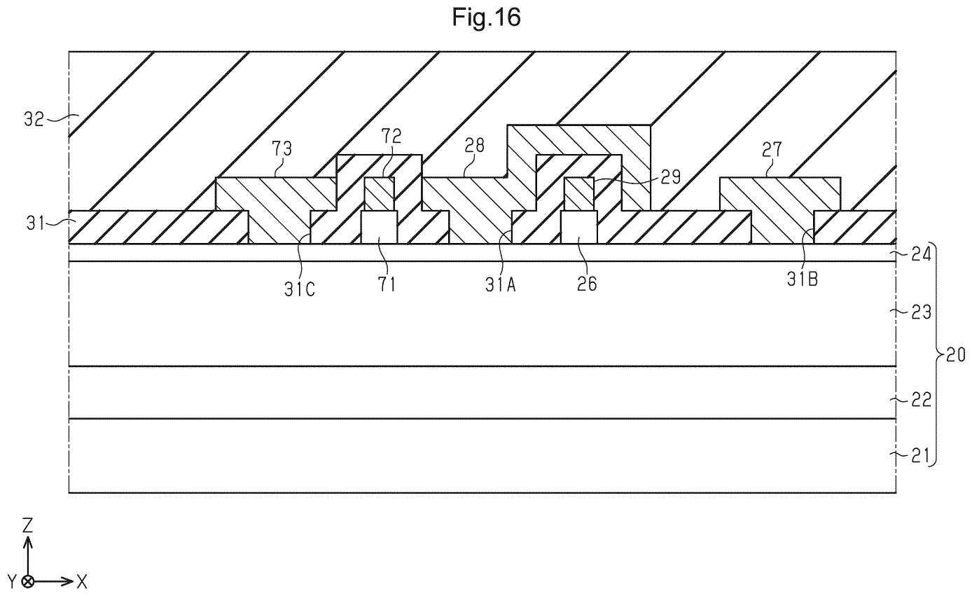

As shown in FIG. 16, the method for manufacturing the nitride semiconductor device 10 includes forming the second insulating layer 32. The second insulating layer 32 may be, for example, a SiO₂ layer. The second insulating layer 32 may be formed by performing, for example, CVD. The upper portion of the second insulating layer 32 may then be flattened. As a result, the upper surface of the second insulating layer 32 will become a flat surface that is orthogonal to the Z-direction.

Although not shown in the drawings, the method for manufacturing the nitride semiconductor device 10 includes forming the drain vias 61, the source vias 62, the gate vias 63, the second peripheral vias 67, and the first peripheral vias 68, forming the drain wiring 51, the source wiring 52, and the gate wiring 53, forming the third insulating layer 33, forming the drain pad vias 64, the source pad vias 65, and the gate pad vias 66, forming the drain pad 41, the source pad 42, and the gate pad 43, forming the peripheral isolation region 81, and forming the protective layer 34.

The vias 61 to 63, 67, and 68 are each formed by forming at least one through hole in the first insulating layer 31 and the second insulating layer 32 to expose part of each of the drain electrode 27, the source electrode 28, the gate electrode 29, the second peripheral electrode 72, and the first peripheral electrode 73. The through holes are then filled with a conductive material. This forms the vias 61 to 63, 67, and 68.

When forming the wirings 51 to 53, for example, sputtering is performed to form a wiring layer above the second insulating layer 32. Then, lithography and etching are performed using a mask to selectively remove the wiring layer. This forms the wirings 51 to 53.

When forming the third insulating layer 33, for example, CVD is performed to form the third insulating layer 33 above the second insulating layer 32. The third insulating layer 33 is formed to cover the wirings 51 to 53.

When forming the vias 64 to 66, through holes are formed in the third insulating layer 33 to expose parts of the wirings 51 to 53. The through holes are filled with a conductive material. This forms the vias 64 to 66.

When forming the pads 41 to 43, for example, sputtering is performed to form a pad layer (conductive layer) above the third insulating layer 33. Then, lithography and etching are performed using a mask to selectively remove the pad layer (conductive layer). This forms the pads 41 to 43.

When forming the peripheral isolation region 81, etching is performed to remove the semiconductor layer 20 from the entire peripheral portion of the electron supply layer 24 and at least part of the peripheral portion of the electron transit layer 23 in the Z-direction. This forms the peripheral isolation region 81. The etching may be mesa etching. In the first embodiment, the peripheral isolation region 81 is formed by performing etching to remove a part of the electron transit layer 23 in the Z-direction. Further, when forming the peripheral isolation region 81, etching may be performed to selectively remove the insulating layer 30.

When forming the protective layer 34, CVD, for example, is performed to form the protective layer 34 above the third insulating layer 33. The protective layer 34 is formed to cover the side surfaces of the first to third insulating layers 31 to 33 and cover the peripheral isolation region 81. When forming the protective layer 34, openings are formed to expose the drain pad 41, the source pad 42, and the gate pad 43. The nitride semiconductor device 10 is manufactured through the steps described above.

### Operation of the First Embodiment

The operation of the nitride semiconductor device 10 in accordance with the first embodiment will now be described.

In the nitride semiconductor device 10, as shown in FIG. 10, the gate layer 26 and the gate electrode 29 form the first Schottky barrier diode SBD1. Further, the gate layer 26, the electron supply layer 24, and the electron transit layer 23 form the first PIN diode PIND1. In the nitride semiconductor device 10, it has been confirmed through experiments that when a reverse-bias surge is applied to the first PIN diode PIND1, the electrostatic discharge (ESD) withstand capability is reduced. In the first PIN diode PIND1, it is understood that the flow of surge current is limited because the amount of reverse leakage current is small and there are no parasitic elements. In contrast, when a reverse bias is applied to the first Schottky barrier diode SBD1, the amount of reverse leakage current is large thereby allowing surge current to flow. It is understood that this increases the ESD withstand capability. Accordingly, with regard to the ESD withstand capability between the gate and source, when negative voltage is applied to the gate electrode 29 and positive voltage is applied to the source electrode 28, ESD-induced surge current flows from the source electrode 28 toward the gate electrode 29. The reverse flow of such a surge current through the first PIN diode PIND1 may cause ESD damage to the transistor cells Tr of the cell region 11 even if the surge voltage is low.

In the nitride semiconductor device 10, the second peripheral electrode 72, the nitride semiconductor layer 71, and the first peripheral electrode 73 are arranged in the peripheral region 12. The nitride semiconductor layer 71, which includes an acceptor impurity, isolates the 2DEG 25 of the peripheral region 12 from the 2DEG 25 of the cell region 11. Accordingly, with regard to the ESD-induced surge voltage between the gate and source, when positive voltage is applied to the source pad 42 and negative voltage is applied to the gate pad 43, surge current flows sequentially through the second peripheral electrode 72, the nitride semiconductor layer 71, the 2DEG 25 of the peripheral region 12, and the first peripheral electrode 73. In other words, surge current flows from the second Schottky barrier diode SBD2 to the second PIN diode PIND2, which are shown in FIG. 10. This limits the flow of surge current to the transistor cells Tr1 to Tr4 of the cell region 11. In this manner, the second peripheral electrode 72, the nitride semiconductor layer 71, and the first peripheral electrode 73 define protective elements protecting the transistor cells Tr1 to Tr4 from surge current.

Advantages of the First Embodiment

The nitride semiconductor device 10 in accordance with the first embodiment has the advantages described below.

(1-1) The nitride semiconductor device 10 includes the semiconductor substrate 21, the electron transit layer 23 located above the semiconductor substrate 21, the electron supply layer 24 located above the electron transit layer 23 and having a larger band gap than the electron transit layer 23, the gate layer 26 formed from a nitride semiconductor including an acceptor impurity and located above a part of the electron supply layer 24, the gate electrode 29 located above the gate layer 26, and the source electrode 28 and the drain electrode 27 located above the electron supply layer 24 and separated from each other. The nitride semiconductor device 10 also includes the cell region 11 in which the gate electrode 29, the source electrode 28, and the drain electrode 27 are arranged, the peripheral region 12 surrounding the cell region 11 in plan view, the nitride semiconductor layer 71 formed from a nitride semiconductor including an acceptor impurity and located in the peripheral region 12, the second peripheral electrode 72 located above the nitride semiconductor layer 71, and the first peripheral electrode 73 located in the peripheral region 12. The first peripheral electrode 73 is electrically connected to the gate electrode 29. The second peripheral electrode 72 is electrically connected to the source electrode 28.

In this configuration, ESD-induced surge current flowing from the source to the gate flows sequentially through the second peripheral electrode 72, the nitride semiconductor layer 71, and the first peripheral electrode 73. Therefore, surge current flows in the peripheral region 12. This limits the flow of surge current in the cell region 11 and allows the ESD withstand capability of the nitride semiconductor device 10 to be increased.

(1-2) The nitride semiconductor layer 71 is located closer to the cell region 11 than the first peripheral electrode 73 is in plan view, and is electrically connected to the transistors in the cell region 11 by the 2DEG 25.

In this configuration, the nitride semiconductor layer 71 is located between the first peripheral electrode 73 and the cell region 11. This reduces the leakage current between the first peripheral electrode 73 and the cell region 11 and reduces the leakage current between the second peripheral electrode 72 and the cell region 11. Further, the element isolation region between the nitride semiconductor layer 71 and the cell region 11 allows the nitride semiconductor device 10 to be reduced in size.

(1-3) The nitride semiconductor layer 71 is looped in plan view.

This configuration further reduces leakage current between the first peripheral electrode 73 and the source electrode 28 of the cell region 11.

(1-4) The first peripheral electrode 73 is looped and surrounds the nitride semiconductor layer 71 and the second peripheral electrode 72 in plan view.

This configuration allows the nitride semiconductor device 10 to be reduced in size, and allows the first peripheral electrode 73 to have sufficient length. Therefore, the ESD withstand capability of the nitride semiconductor device 10 can be increased.

(1-5) The total length of the first peripheral electrode 73 is between 1% and 40%, inclusive, of the total length of the gate electrodes 29.

In this configuration, the total length of the first peripheral electrode 73 is greater than or equal to 1% of the total length of the gate electrodes 29. This allows the first peripheral electrode 73 to have sufficient length. Therefore, the ESD withstand capability of the nitride semiconductor device 10 can be increased. Further, the total length of the first peripheral electrode 73 is less than or equal to 40% of the total length of the gate electrode 29. This avoids a situation in which the gate capacitance becomes excessive. Therefore, the switching speed of the nitride semiconductor device 10 can be maintained.

(1-6) The total length of the first peripheral electrode 73 is between 5% and 20%, inclusive, of the total length of the gate electrodes 29.

The total length of the first peripheral electrode 73 is greater than or equal to 5% of the total length of the gate electrode 29. This allows the first peripheral electrode 73 to have sufficient length. Therefore, the ESD withstand capability of the nitride semiconductor device 10 can be further increased. Further, the total length of the first peripheral electrode 73 is less than or equal to 20% of the total length of the gate electrodes 29. This avoids a situation in which the gate capacitance becomes excessive. Therefore, the switching speed of the nitride semiconductor device 10 can be maintained.

(1-7) The gate layer 26 has an impurity concentration between 1×10¹⁸ cm⁻³ and 1×10¹⁹ cm⁻³, inclusive.

In this configuration, the impurity concentration of the gate layer 26 is low, and the activating rate of the gate layer 26 is high. This allows the ESD withstand capability of the nitride semiconductor device 10 to be increased when the surge voltage between the gate and source applies positive voltage to the gate electrode 29 and negative voltage to the source electrode 28.

(1-8) The gate layer 26 has an impurity concentration between 2×10¹⁸ cm⁻³ and 5×10¹⁸ cm⁻³.

In this configuration, the impurity concentration of the gate layer 26 is low, and the activating rate of the gate layer 26 is high. This allows the ESD withstand capability of the nitride semiconductor device 10 to be increased when the surge voltage between the gate and source applies positive voltage to the gate electrode 29 and negative voltage to the source electrode 28.

(1-9) The gate electrode 29 and the gate layer 26 form a Schottky junction. In this case, it is difficult to integrate a protective diode, which is connected in inverse parallel to the drain and source of a transistor in the nitride semiconductor device 10, as a PN junction in the same semiconductor layer 20. In this respect, in the present embodiment, the nitride semiconductor layer 71, the second peripheral electrode 72, and the first peripheral electrode 73 define protective elements in the peripheral region 12 of the semiconductor layer 20. This protects the transistors of the nitride semiconductor device 10 from electrostatic discharge without using the protective diode described above.

(1-10) The portion of the gate electrode 29 that contacts the gate layer 26 includes at least one of TiN, TaN, WN, TiSiN, TaSiN, WSi, and WSiN.

This configuration forms a Schottky junction with the gate electrode 29 and the gate layer 26, and facilitates processing of the gate electrode 29 by performing, for example, dry etching.

(1-11) The method for manufacturing the nitride semiconductor device 10 includes forming the electron transit layer 23 above the semiconductor substrate 21, forming the electron supply layer 24 having a larger band gap than the electron transit layer 23 above the electron transit layer 23, forming the gate layer 26 from a nitride semiconductor including an acceptor impurity above a part of the electron supply layer 24, forming the gate electrode 29 above the gate layer 26, and forming the source electrode 28 and the drain electrode 27 separated from each other above the electron supply layer 24. The nitride semiconductor device 10 includes the cell region 11, in which the gate electrode 29, the source electrode 28, and the drain electrode 27 are arranged, and the peripheral region 12 surrounding the cell region 11 in plan view. The method for manufacturing the nitride semiconductor device 10 includes forming the nitride semiconductor layer 71 from a nitride semiconductor including an acceptor impurity in the peripheral region 12 above the electron supply layer 24, forming a second peripheral electrode 72, electrically connected to the source electrode 28, above the nitride semiconductor layer 71, and forming the first peripheral electrode 73 electrically connected to the gate electrode 29 in the peripheral region 12.

In this configuration, ESD-induced surge current, which flows from the source to the gate, flows sequentially through the second peripheral electrode 72, the nitride semiconductor layer 71, and the first peripheral electrode 73. Therefore, surge current flows in the peripheral region 12. This limits the flow of surge current in the cell region 11 and allows the ESD withstand capability of the nitride semiconductor device 10 to be increased.

(1-12) The nitride semiconductor layer 71 and the gate layer 26 are formed in the same step. The nitride semiconductor layer 71 and the gate layer 26 are equal in impurity concentration.

In this configuration, the nitride semiconductor layer 71 and the gate layer 26 are formed in the same step. Therefore, the dopant amount of the nitride semiconductor layer 71 and the dopant amount of the gate layer 26 do not have to be changed. This simplifies the manufacturing process of the nitride semiconductor device 10.

(1-13) The gate electrode 29 and the second peripheral electrode 72 are formed in the same step. The gate electrode 29 and the second peripheral electrode 72 are formed from the same material.

In this configuration, the gate electrode 29 and the second peripheral electrode 72 are formed from the same material in the same step. This simplifies the manufacturing process of the nitride semiconductor device 10.

(1-14) The drain electrode 27, the source electrode 28, and the first peripheral electrode 73 are formed in the same step. The drain electrode 27, the source electrode 28, and the first peripheral electrode 73 are formed from the same material.

In this configuration, the drain electrode 27, the source electrode 28, and the first peripheral electrode 73 are formed from the same material in the same step. This simplifies the manufacturing process of the nitride semiconductor device 10.

(1-15) The peripheral isolation region 81 includes the recess 81A extending through the electron supply layer 24 and at least part of the electron transit layer 23 in the Z-direction. The recess 81A is formed by performing etching. This facilitates formation of the peripheral isolation region 81.

### SECOND EMBODIMENT

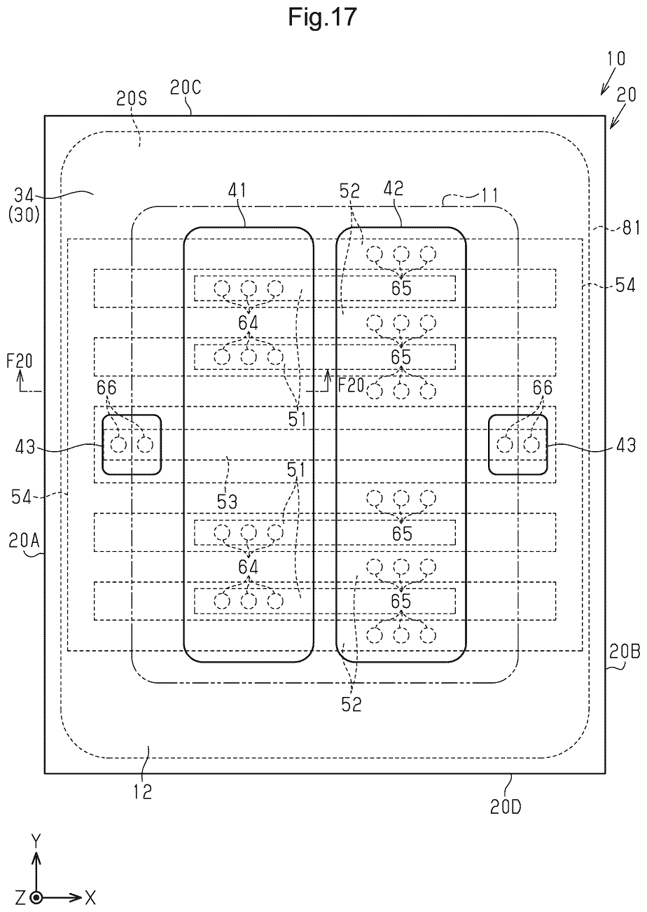

With reference to FIGS. 17 to 20, a nitride semiconductor device 10 in accordance with a second embodiment will now be described. The nitride semiconductor device 10 in accordance with the second embodiment differs from the nitride semiconductor device 10 in accordance with the first embodiment mainly in the configuration of the peripheral region 12. The same reference characters are given to those components that are the same as the corresponding components of the first embodiment. Such components will not be described in detail.

### Configuration of the Nitride Semiconductor Device

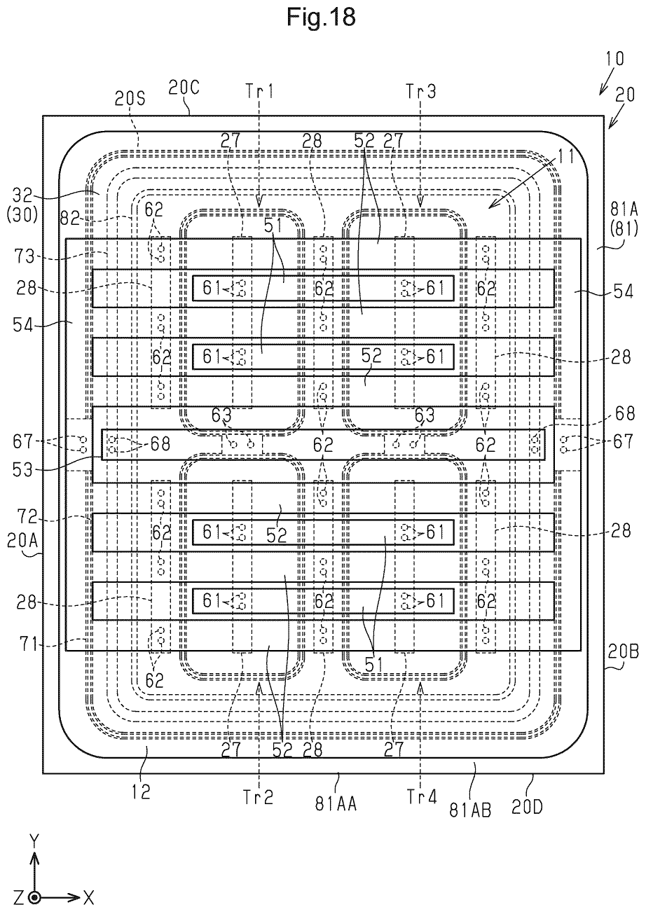

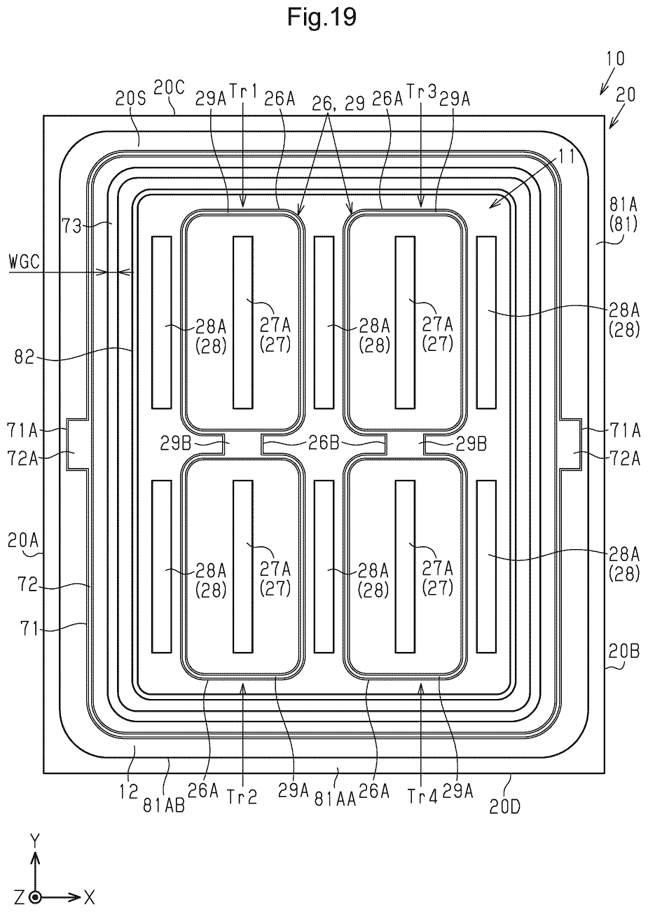

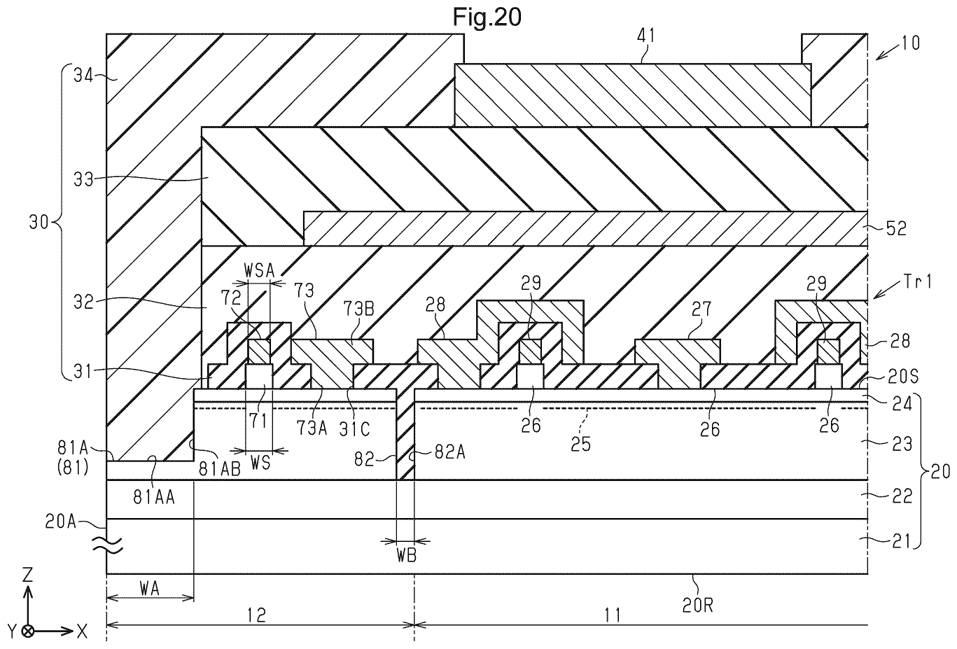

With reference to FIGS. 17 to 20, the configuration of the nitride semiconductor device 10 in accordance with the second embodiment will now be described. FIG. 17 is a schematic plan view of the nitride semiconductor device 10. FIG. 18 is a schematic plan view showing the nitride semiconductor device 10 of FIG. 17 without the drain pad 41, the source pad 42, and the gate pads 43. FIG. 19 is a schematic plan view showing the nitride semiconductor device 10 of FIG. 18 without the drain wiring 51, the source wiring 52, and the gate wiring 53. FIG. 20 is a schematic cross-sectional view of the nitride semiconductor device 10 taken along line F20-F20 in FIG. 17.

As shown in FIGS. 18 and 19, in the nitride semiconductor device 10 in accordance with the second embodiment, the positional relationship of the first peripheral electrode 73 with respect to the nitride semiconductor layer 71 and the second peripheral electrode 72 differs from the first embodiment. In the second embodiment, the first peripheral electrode 73 is located closer to the cell region 11 than the second peripheral electrode 72 is in plan view. The first peripheral electrode 73 is located closer to the cell region 11 than the nitride semiconductor layer 71 is in plan view.

The nitride semiconductor device 10 in accordance with the second embodiment further includes an element isolation region 82 located between the cell region 11 and the peripheral region 12. The element isolation region 82 electrically isolates the cell region 11 and the peripheral region 12. The element isolation region 82 is looped and surrounds the cell region 11 in plan view. Therefore, in the second embodiment, in the nitride semiconductor device 10, the cell region 11 is located inward from the element isolation region 82 in plan view, and the peripheral region 12 is located closer to the edges of the semiconductor layer 20 than the element isolation region 82 is in plan view.

In an example, the element isolation region 82 has the shape of a quadrilateral loop in plan view. In an example, the four corners of the element isolation region 82, which has the shape of a quadrilateral loop, are curved outward. As shown in FIG. 19, the element isolation region 82 is located between the first peripheral electrode 73 and the source electrode 28. Therefore, the first peripheral electrode 73 is arranged in the peripheral region 12. In an example, a first distance in the X-direction between the element isolation region 82 and the source contact 28A of the outermost source electrode 28 in the cell region 11 may be less than a second distance in the X-direction between the element isolation region 82 and the first peripheral electrode 73. In another example, the first distance may be greater than or equal to the second distance.

As shown in FIG. 20, the element isolation region 82 includes a recess 82A extending through the electron supply layer 24 and at least part of the electron transit layer 23 in the Z-direction. Therefore, in the element isolation region 82, the electron supply layer 24 is removed from the semiconductor layer 20. In the example shown in FIG. 20, the element isolation region 82 extends through the electron transit layer 23 in the Z-direction. Therefore, in the element isolation region 82, the electron transit layer 23 is removed from the semiconductor layer 20. The element isolation region 82 exposes the buffer layer 22 in the Z-direction. In the example shown in FIG. 20, the electron transit layer 23 and the electron supply layer 24 are both removed by performing etching (e.g., mesa etching) to form the element isolation region 82. In an example, the recess 82A of the element isolation region 82 has a greater depth than the recess 81A of the peripheral isolation region 81. In an example, a width of the recess 82A of the element isolation region 82 (width WB of element isolation region 82) is less than a width of the recess 81A of the peripheral isolation region 81 (width WA of peripheral isolation region 81). In other words, the width WA of the peripheral isolation region 81 is greater than the width WB of the element isolation region 82. In an example, the element isolation region 82 is filled with the first insulating layer 31. The element isolation region 82, however, does not have to be filled with the first insulating layer 31.

The depth of the recess 82A in the element isolation region 82 may be defined as the distance between the first surface 20S of the semiconductor layer 20 and the bottom surface of the recess 82A (surface of buffer layer 22) in the Z-direction. The depth of the recess 81A in the peripheral isolation region 81 may be defined as the distance between the first surface 20S of the semiconductor layer 20 and the bottom surface of the recess 81A (surface of buffer layer 22) in the Z-direction. The width of the recess 82A in the element isolation region 82 may be defined as the dimension in the direction orthogonal to the direction in which the recess 82A extends in plan view. The width of the recess 81A in the peripheral isolation region 81 may be defined as the dimension in the direction orthogonal to the direction in which the recess 81A extends in plan view.

In an example, the element isolation region 82 is filled with the first insulating layer 31. In the example shown in FIG. 20, the element isolation region 82 is entirely filled with the first insulating layer 31 without any voids. The relationship between the element isolation region 82 and the first insulating layer 31 may be changed. In an example, the element isolation region 82 may be partially filled with the first insulating layer 31. In this case, a void may be formed in the element isolation region 82.

The first peripheral electrode 73 is located between the element isolation region 82 and the nitride semiconductor layer 71 in plan view. The first peripheral electrode 73 is looped and surrounds the element isolation region 82 in plan view. In an example, the first peripheral electrode 73 has the shape of a quadrilateral loop in plan view. In an example, the four corners of the first peripheral electrode 73, which has the shape of a quadrilateral loop, are curved outward.

The nitride semiconductor layer 71 is located between the first peripheral electrode 73 and the peripheral isolation region 81 in plan view. The nitride semiconductor layer 71 is looped and surrounds the first peripheral electrode 73 in plan view. In an example, the nitride semiconductor layer 71 has the shape of a quadrilateral loop in plan view. In an example, the four corners of the nitride semiconductor layer 71, which has the shape of a quadrilateral loop, are curved outward.

The second peripheral electrode 72, which is located above the nitride semiconductor layer 71, is looped and surrounds the first peripheral electrode 73 in plan view. In an example, the second peripheral electrode 72 has the shape of a quadrilateral loop in plan view. In an example, the four corners of the second peripheral electrode 72, which has the shape of a quadrilateral loop, are curved outward.

As shown in FIGS. 17 and 19, the nitride semiconductor layer 71 and the second peripheral electrode 72 are both located closer to the edges of the semiconductor layer 20 in the X-direction than the gate pads 43 are. As shown in FIG. 18, the nitride semiconductor layer 71 and the second peripheral electrode 72 are both located closer to the edges of the semiconductor layer 20 in the X-direction than the gate wiring 53 is.

As shown in FIG. 19, the width WGC of the first peripheral electrode 73 is greater than the width WB of the element isolation region 82 (refer to FIG. 20). The width WSA of the second peripheral electrode 72 (refer to FIG. 20) is greater than the width WB of the element isolation region 82. The width WB of the element isolation region 82 may be defined as the dimension in the direction orthogonal to the direction in which the element isolation region 82 extends in plan view.

As shown in FIG. 18, the source connecting wirings 54 are located closer to the edges of the semiconductor layer 20 in the X-direction than the gate wiring 53 is. The source connecting wirings 54 overlap the second peripheral electrode 72 in plan view. In an example, the source connecting wirings 54 extend in the Y-direction to connect all of the source wirings 52, which are spaced apart from one another in the Y-direction.

The widened portion 71A of the nitride semiconductor layer 71 and the widened portion 72A of the second peripheral electrode 72 are both located closer to the edges of the semiconductor layer 20 in the X-direction than the gate pad 43 is. Further, the widened portions 71A and 72A are located closer to the edges of the semiconductor layer 20 in the X-direction than the gate wiring 53 is. The widened portions 71A and 72A overlap the source connecting wirings 54 in plan view. As shown in FIG. 19, the widened portions 71A and 72A extend away from the first peripheral electrode 73 in plan view.

### Method for Manufacturing the Nitride Semiconductor Device

A method for manufacturing the nitride semiconductor device 10 in accordance with the second embodiment differs from the first embodiment in that the element isolation region 82 is additionally formed. In an example, the method for manufacturing the nitride semiconductor device 10 includes forming the element isolation region 82, which electrically isolates the cell region 11 and the peripheral region 12, between the cell region 11 and the peripheral region 12. When forming the element isolation region 82, etching is performed to form the element isolation region 82. The element isolation region 82 is formed before the peripheral isolation region 81 is formed. In an example, the element isolation region 82 may be formed between when the gate electrode 29 and the second peripheral electrode 72 are formed and when the first insulating layer 31 is formed. In this case, the recess 82A of the element isolation region 82 is filled with part of the first insulating layer 31.

### Advantages of the Second Embodiment

The nitride semiconductor device 10 in accordance with the second embodiment has the advantages described below.

(2-1) The nitride semiconductor device 10 includes the element isolation region 82 that electrically isolates the cell region 11 and the peripheral region 12. The element isolation region 82 is located between the cell region 11 and the peripheral region 12. The first peripheral electrode 73 is located closer to the cell region 11 than the second peripheral electrode 72 is in plan view. The element isolation region 82 is located between the first peripheral electrode 73 and the cell region 11.

In this configuration, the element isolation region 82, which electrically isolates the cell region 11 and the peripheral region 12, reduces leakage current between the second peripheral electrode 72 and the source electrode 28 of the cell region 11 and between the second peripheral electrode 72 and the drain electrode 27 of the cell region 11.

(2-2) The element isolation region 82 is looped and surrounds the cell region 11 in plan view. The first peripheral electrode 73 is looped and surrounds the element isolation region 82 in plan view.

In this configuration, the looped element isolation region 82 increases the effect for reducing leakage current between the second peripheral electrode 72 and the source electrode 28 of the cell region 11 and between the second peripheral electrode 72 and the drain electrode 27 of the cell region 11. Further, the first peripheral electrode 73, which is looped and surrounds the element isolation region 82, allows the nitride semiconductor device 10 to be reduced in size and allows the first peripheral electrode 73 to have sufficient strength. Therefore, the ESD withstand capability of the nitride semiconductor device 10 can be increased.

(2-3) The nitride semiconductor layer 71 is looped and surrounds the first peripheral electrode 73 in plan view.

In this configuration, the second peripheral electrode 72 surrounds the first peripheral electrode 73 and the cell region 11 above the nitride semiconductor layer 71. This stabilizes the potential at the peripheral region 12 in the nitride semiconductor device 10. Further, the second peripheral electrode 72, above the nitride semiconductor layer 71, covers the edges of the semiconductor layer 20. This limits, in the insulating layer 30, the movement of ions and the movement of moisture that is induced by an electric field. Therefore, the reliability of the nitride semiconductor device 10 with respect to moisture resistance is increased.

(2-4) The element isolation region 82 extends throughout the electron transit layer 23 in the thickness direction (Z-direction). Therefore, the element isolation region 82 increases the effect for reducing leakage current between the second peripheral electrode 72 and the source electrode 28 of the cell region 11 and between the second peripheral electrode 72 and the drain electrode 27 of the cell region 11.

(2-5) The element isolation region 82 includes the recess 82A extending through the electron supply layer 24 and at least part of the electron transit layer 23 in the Z-direction. The recess 82A is formed by performing etching. This facilitates formation of the element isolation region 82.

### THIRD EMBODIMENT

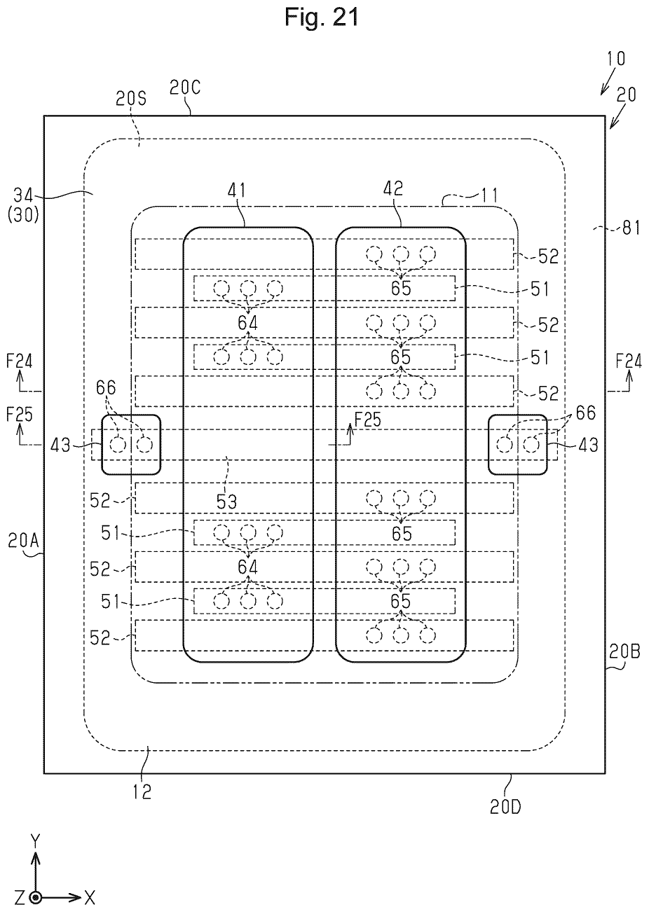

With reference to FIGS. 21 to 27, a nitride semiconductor device 10 in accordance with a third embodiment will now be described. The nitride semiconductor device 10 in accordance with the third embodiment differs from the nitride semiconductor device 10 in accordance with the second embodiment mainly in the configuration of the peripheral region 12. The same reference characters are given to those components that are the same as the corresponding components of the second embodiment. Such components will not be described in detail.

### Configuration of the Nitride Semiconductor Device

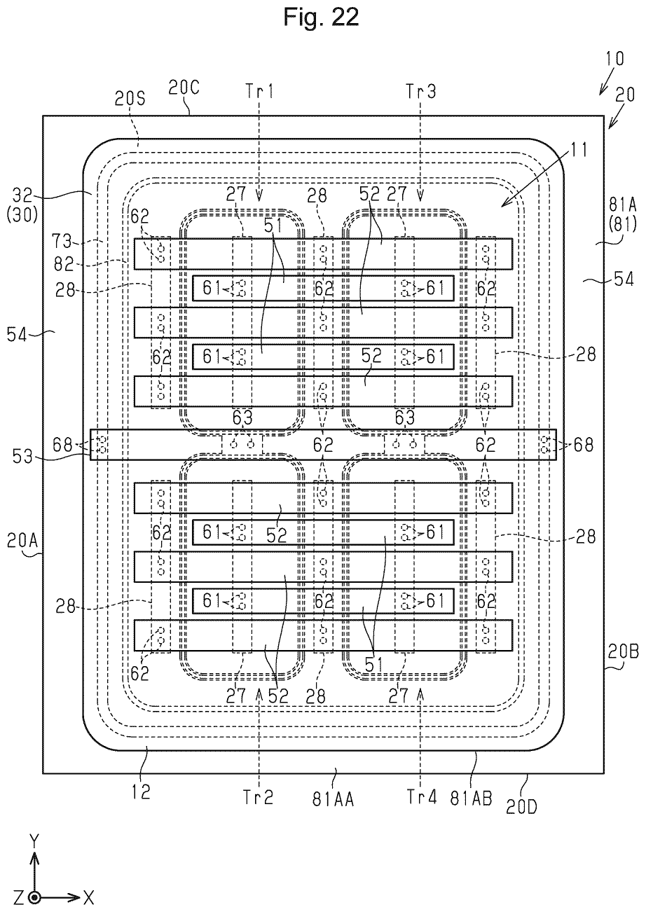

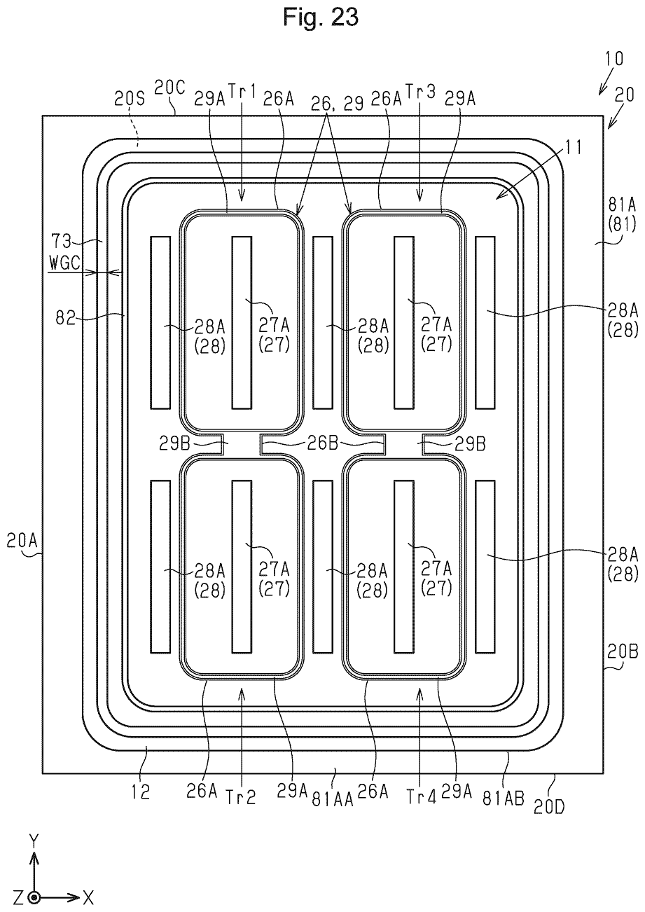

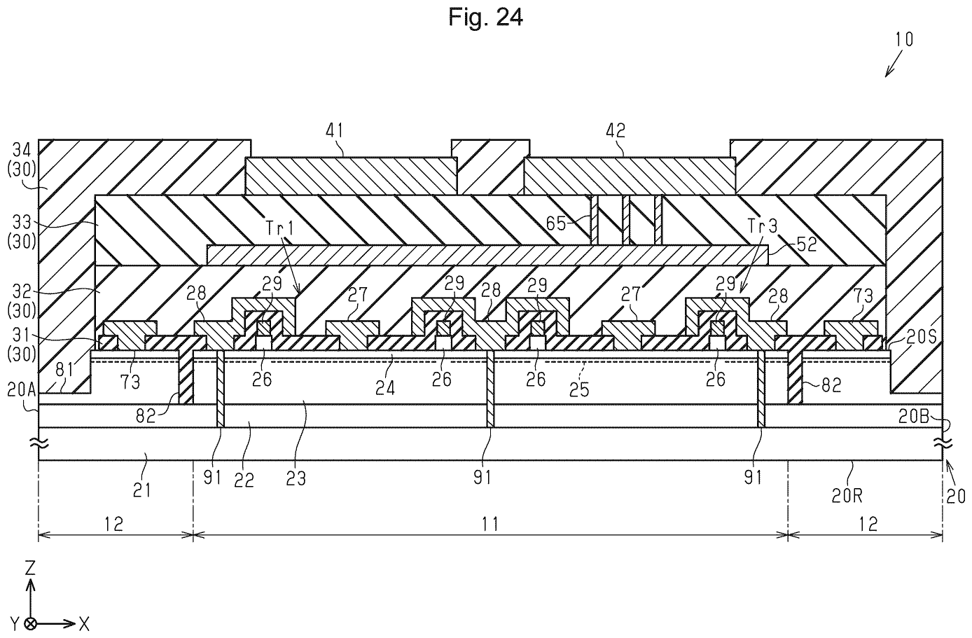

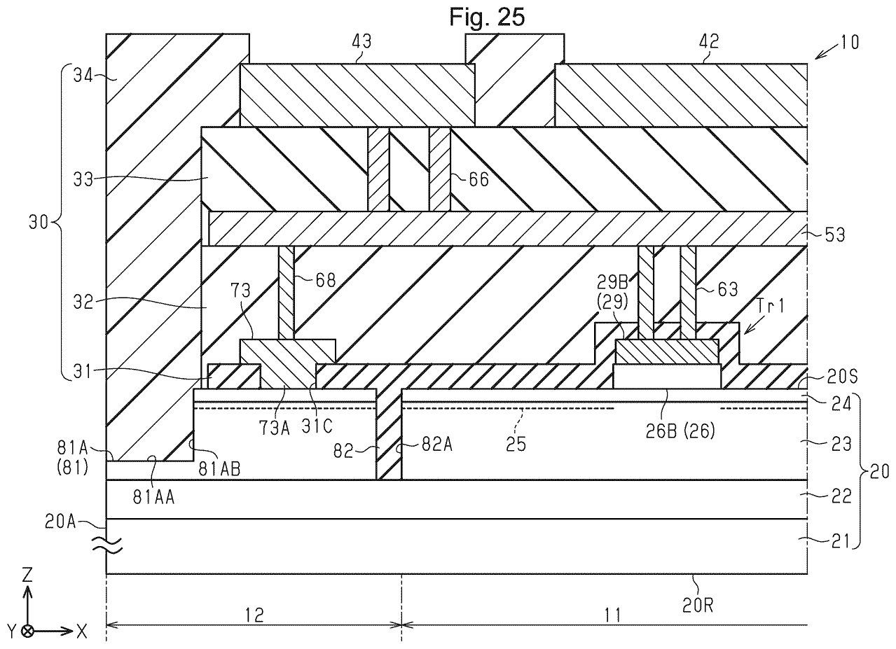

With reference to FIGS. 21 to 25, the configuration of the nitride semiconductor device 10 in accordance with the third embodiment will now be described. FIG. 21 is a schematic plan view of the nitride semiconductor device 10 in accordance with the third embodiment. FIG. 22 is a schematic plan view showing the nitride semiconductor device 10 of FIG. 21 without the drain pad 41, the source pad 42, and the gate pads 43. FIG. 23 is a schematic plan view showing the nitride semiconductor device 10 of FIG. 22 without the drain wiring 51, the source wiring 52, and the gate wiring 53. FIG. 24 is a schematic cross-sectional view of the nitride semiconductor device 10 taken along line F24-F24 in FIG. 21. FIG. 25 is a schematic cross-sectional view of the nitride semiconductor device 10 taken along line F25-F25 in FIG. 21 and shows the first peripheral electrode 73 in an enlarged manner.

As shown in FIGS. 21 to 23, the nitride semiconductor device 10 in accordance with the third embodiment corresponds to a configuration in which the nitride semiconductor layer 71 and the second peripheral electrode 72 are omitted from the nitride semiconductor device 10 in accordance with the second embodiment. Therefore, the nitride semiconductor device 10 in accordance with the third embodiment includes the element isolation region 82, which electrically isolates the cell region 11 and the peripheral region 12, and the first peripheral electrode 73, which is located in the peripheral region 12. The element isolation region 82 is located between the cell region 11 and the peripheral region 12 in the same manner as the second embodiment. The shape of the element isolation region 82 in plan view and the shape of the first peripheral electrode 73 in plan view are the same as the corresponding shapes in the second embodiment. The cross-sectional shape of the element isolation region 82 taken along a plane extending in the Z-direction is the same as that of the second embodiment. As shown in FIGS. 23 and 24, the element isolation region 82 has the same width and depth as that of the second embodiment. The first peripheral electrode 73 has the same width as that of the second embodiment. The positional relationship of the gate wiring 53 and the gate pad 43 is the same as that of the first embodiment.

As shown in FIG. 22, the source connecting wirings 54 are omitted. Each source wiring 52 is located inward from the element isolation region 82 in plan view.

In the example shown in FIG. 23, the distance between the element isolation region 82 and the first peripheral electrode 73 in the X-direction is less than the distance between the element isolation region 82 and the outermost source contact 28A of the source electrode 28 of the cell region 11 in the X-direction. Therefore, in the X-direction, the element isolation region 82 is located closer to the first peripheral electrode 73 than the outermost source contact 28A of the source electrode 28 in the cell region 11 is.

As shown in FIG. 24, the nitride semiconductor device 10 includes a via 91 electrically connecting the source electrode 28 and the semiconductor substrate 21 in the Z-direction. The via 91 extends through both the electron supply layer 24 and the electron transit layer 23 in the cell region 11. The via 91 further extends through the buffer layer 22. Therefore, the via 91 is in contact with both of the source electrode 28 and the semiconductor substrate 21. The via 91 may be formed from a material including at least one of Ti, TiN, Au, Ag, Cu, Al, and W. In this manner, the semiconductor substrate 21 is electrically connected to the source electrode 28. There is no limitation to the number of the vias 91. In an example, the via 91 may be one of a plurality of vias 91.

As shown in FIG. 25, the electrical connection structure of the first peripheral electrode 73 and the gate electrode 29 is the same as that of the first embodiment (second embodiment). More specifically, the gate vias 63 connect the gate electrode 29 and the gate wiring 53, and the first peripheral vias 68 connect the first peripheral electrode 73 and the gate wiring 53.

### Method for Manufacturing the Nitride Semiconductor Device

A method for manufacturing the nitride semiconductor device 10 in accordance with the third embodiment differs from the second embodiment in that the source electrode 28 is formed to be electrically connected to the semiconductor substrate 21 and in that the nitride semiconductor layer 71 and the second peripheral electrode 72 are not formed.

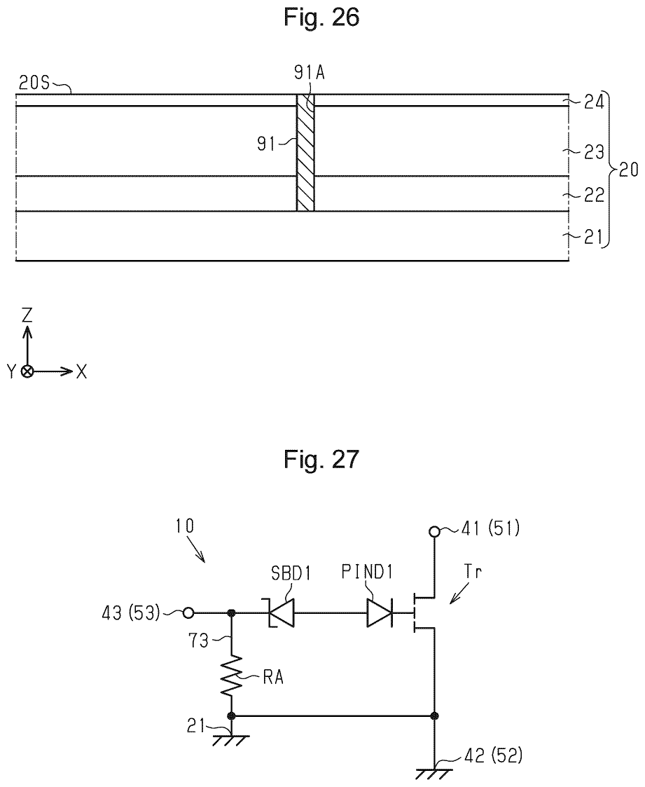

With reference to FIG. 26, a step added in the method for manufacturing the nitride semiconductor device 10 will now be described.

The method for manufacturing the nitride semiconductor device 10 includes forming the vias 91 that connect the source electrode 28 and the semiconductor substrate 21 in order to electrically connect the source electrode 28 and the semiconductor substrate 21. In this step, for example, etching is first performed to form a through hole 91A in the semiconductor layer 20. The through hole 91A extends through the electron supply layer 24, the electron transit layer 23, and the buffer layer 22 in the Z-direction. The through hole 91A exposes the semiconductor substrate 21. Then, the through hole 91A is filled with a conductive material. The conductive material forms the via 91. This forms the via 91 that contacts the semiconductor substrate 21. For example, the via 91 is a cylindrical component exposed from the first surface 20S of the semiconductor layer 20.

Although not shown in the drawings, the drain electrode 27, the source electrode 28, and the first peripheral electrode 73 are formed so that the source electrode 28 contacts the vias 91. Accordingly, the vias 91 electrically connect the source electrode 28 to the semiconductor substrate 21.

### Operation of the Third Embodiment

With reference to FIGS. 24, 25, and 27, the operation of the nitride semiconductor device 10 in accordance with the third embodiment will now be described. FIG. 27 is a schematic circuit diagram of the nitride semiconductor device 10.

The nitride semiconductor device 10 in accordance with the third embodiment includes a resistor RA formed by the buffer layer 22 and the electron transit layer 23. As shown in FIG. 25, the first peripheral electrode 73 is electrically connected to the gate pad 43 by the first peripheral vias 68, the gate wiring 53, and the gate pad vias 66. As shown in FIG. 24, the first peripheral electrode 73 is electrically connected to the semiconductor substrate 21 by the electron transit layer 23 and the buffer layer 22, which form the resistor RA. The semiconductor substrate 21 is electrically connected to the vias 91 and the source electrode 28. In the same manner as the first embodiment, the source electrode 28 is electrically connected to the source pad 42. Accordingly, the resistor RA is connected between the gate electrode 29 and the source pad 42.

When surge voltage between the gate and source applies negative voltage to the gate pad 43 and applies positive voltage to the source pad 42, surge current acts to flow from the semiconductor substrate 21, which is electrically connected to the source electrode 28, toward the gate pad 43. The first peripheral electrode 73, which is electrically connected to the gate pad 43, is in ohmic contact with the electron supply layer 24. Accordingly, the surge current flows through the first peripheral electrode 73 toward the gate pad 43 and does not flow to the gate electrode 29. As shown in FIG. 27, the gate electrode 29 of the nitride semiconductor device 10 is electrically connected by the resistor RA (buffer layer 22 and electron transit layer 23) to the source pad 42. Accordingly, the surge current flows through the resistor RA to the first peripheral electrode 73. In this manner, the flow of surge current in the cell region 11 is limited.

### Advantages of the Third Embodiment

In addition to advantages (2-1), (2-2), (2-4), and (2-5) of the second embodiment, the nitride semiconductor device 10 in accordance with the third embodiment has the advantage described below.

(3-1) The nitride semiconductor device 10 includes the semiconductor substrate 21, the electron transit layer 23 located above the semiconductor substrate 21, the electron supply layer 24 located above the electron transit layer 23 and having a larger band gap than the electron transit layer 23, the gate layer 26 formed from a nitride semiconductor including an acceptor impurity and located above a part of the electron supply layer 24, the gate electrode 29 located above the gate layer 26, and the source electrode 28 and the drain electrode 27 located above the electron supply layer 24 and separated from each other. The nitride semiconductor device 10 includes the cell region 11, in which the gate electrode 29, the source electrode 28, and the drain electrode 27 are arranged, the peripheral region 12 surrounding the cell region 11 in plan view, the element isolation region 82 located between the cell region 11 and the peripheral region 12 and electrically isolating the cell region 11 and the peripheral region 12, and the first peripheral electrode 73 located in the peripheral region 12. The semiconductor substrate 21 is electrically connected to the source electrode 28. The first peripheral electrode 73 is electrically connected to the gate electrode 29.

In this configuration, when surge voltage between the gate and source applies negative voltage to the gate electrode 29 and applies positive voltage to the source electrode 28, surge current flows from the semiconductor substrate 21 to the first peripheral electrode 73. This limits the flow of surge current in the cell region 11. Therefore, the ESD withstand capability of the nitride semiconductor device 10 can be increased.

### FOURTH EMBODIMENT

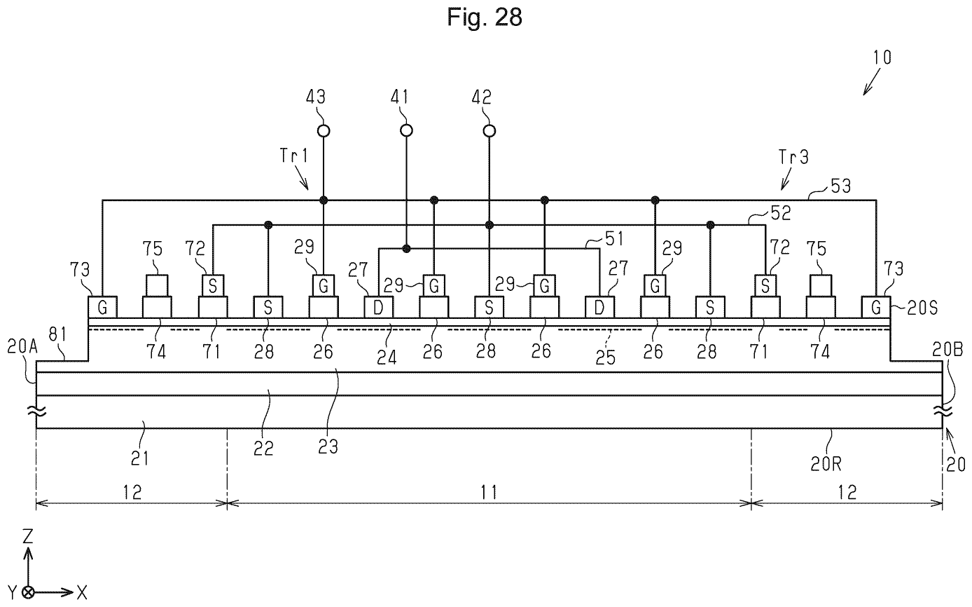

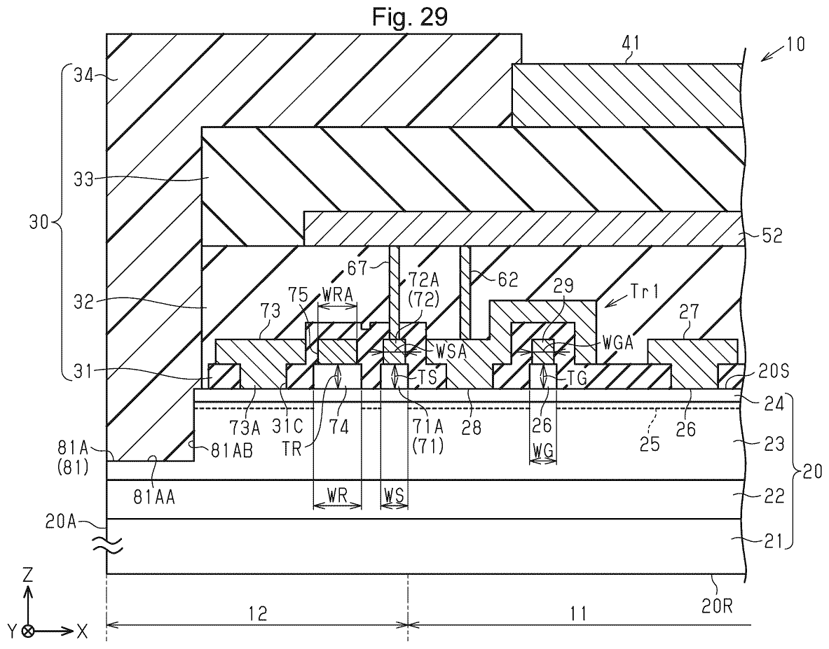

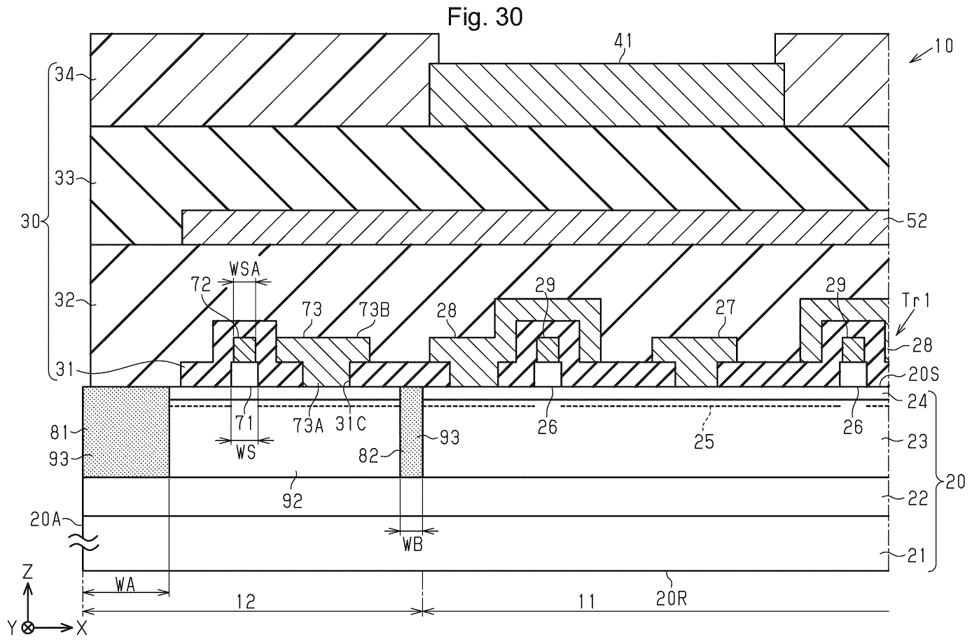

With reference to FIGS. 28 and 29, a nitride semiconductor device 10 in accordance with the fourth embodiment will now be described. The nitride semiconductor device 10 in accordance with the fourth embodiment differs from the nitride semiconductor device 10 in accordance with the first embodiment mainly in the configuration of the peripheral region 12. The same reference characters are given to those components that are the same as the corresponding components of the first embodiment. Such components will not be described in detail. FIG. 28 schematically shows the electrical connection structure of the nitride semiconductor device 10 in accordance with the fourth embodiment. FIG. 29 is a schematic cross-sectional view showing the peripheral region 12 of the nitride semiconductor device 10.

### Configuration of the Nitride Semiconductor Device

As shown in FIG. 28, the nitride semiconductor device 10 in accordance with the fourth embodiment includes a nitride semiconductor layer 74 and a third peripheral electrode 75, which are arranged in the peripheral region 12. The third peripheral electrode 75 is located above the nitride semiconductor layer 74. In an example, the nitride semiconductor layer 74 is in an electrically floating state. The potential at the nitride semiconductor layer 74 differs from the potential at the first peripheral electrode 73. The potential at the nitride semiconductor layer 74 differs from the potential at the nitride semiconductor layer 71. The potential at the nitride semiconductor layer 74 differs from the potential at the source electrode 28. In an example, the third peripheral electrode 75 is in an electrically floating state. The nitride semiconductor layer 74 is one example of a second nitride semiconductor layer, and the nitride semiconductor layer 71 is one example of a first nitride semiconductor layer.

The nitride semiconductor layer 74 and the third peripheral electrode 75 are located between the second peripheral electrode 72 and the first peripheral electrode 73 in plan view. The nitride semiconductor layer 74 is spaced apart from the nitride semiconductor layer 71. The nitride semiconductor layer 74 is looped and surrounds the nitride semiconductor layer 71 in plan view. In an example, the nitride semiconductor layer 74 has the shape of a closed loop in plan view. In an example, the nitride semiconductor layer 74 has the shape of a quadrilateral loop in plan view. In an example, the four corners of the nitride semiconductor layer 74, which has the shape of a quadrilateral loop, are curved outward. The third peripheral electrode 75 is looped and surrounds the second peripheral electrode 72 in plan view. In an example, the third peripheral electrode 75 has the shape of a closed loop in plan view. In an example, the third peripheral electrode 75 has the shape of a quadrilateral loop in plan view. In an example, the four corners of the third peripheral electrode 75, which has the shape of a quadrilateral loop, are curved outward.

As shown in FIG. 29, the nitride semiconductor layer 74 is located above the electron supply layer 24. In an example, the position of the nitride semiconductor layer 74 in the Z-direction corresponds to the position of the nitride semiconductor layer 71 in the Z-direction. The nitride semiconductor layer 74 is formed from a nitride semiconductor. In an example, the nitride semiconductor layer 74 has a smaller band gap than the electron supply layer 24 and is formed from a nitride semiconductor including an acceptor impurity. In an example, the nitride semiconductor layer 74 is a GaN (p-type GaN) layer doped with the acceptor impurity. The acceptor impurity may be at least one of Mg, Zn, and C. In an example, the nitride semiconductor layer 74 has an impurity concentration between 1×10¹⁸ cm⁻³ and 1×10¹⁹ cm⁻³, inclusive. Further, in an example, the nitride semiconductor layer 74 has an impurity concentration between 2×10¹⁸ cm⁻³ and 5×10¹⁸ cm⁻³, inclusive. In an example, the nitride semiconductor layer 74 and the gate layer 26 may be equal in impurity concentration. In an example, the nitride semiconductor layer 74 and the nitride semiconductor layer 71 may be equal in impurity concentration. The nitride semiconductor layer 74 may have any impurity concentration. In an example, the impurity concentration of the nitride semiconductor layer 74 may differ from that of the gate layer 26. In an example, the impurity concentration of the nitride semiconductor layer 71 may differ from that of the nitride semiconductor layer 74.

In an example, a width WR of the nitride semiconductor layer 74 is greater than the width WG of the gate layer 26. In an example, the width WR of the nitride semiconductor layer 74 may be greater than or equal to two times the width WG of the gate layer 26. In an example, the width WR of the nitride semiconductor layer 74 may be less than or equal to twenty-five times the width WG of the gate layer 26. In an example, the width WR of the nitride semiconductor layer 74 may be in a range of at least one of between two times and five times, inclusive, the width WG of the gate layer 26, between five times and ten times, inclusive, the width WG of the gate layer 26, between ten times and fifteen times, inclusive, the width WG of the gate layer 26, between fifteen times and twenty times, inclusive, the width WG of the gate layer 26, and between twenty times and twenty-five times, inclusive, the width WG of the gate layer 26. In an example, the width WR of the nitride semiconductor layer 74 is between five times and fifteen times, inclusive, the width WG of the gate layer 26.

In an example, the width WR of the nitride semiconductor layer 74 is greater than the width WS of the nitride semiconductor layer 71. In an example, the width WR of the nitride semiconductor layer 74 may be greater than or equal to two times the width WS of the nitride semiconductor layer 71. In an example, the width WR of the nitride semiconductor layer 74 may be less than or equal to twenty-five times the width WS of the nitride semiconductor layer 71. The width WR of the nitride semiconductor layer 74 may be defined as the dimension in the direction orthogonal to the direction in which the nitride semiconductor layer 74 extends in plan view. The nitride semiconductor layer 74 may have a thickness TR that is equal to the thickness TG of the gate layer 26. The thickness TR of the nitride semiconductor layer 74 may be equal to the thickness TS of the nitride semiconductor layer 71.

The third peripheral electrode 75 is in contact with the nitride semiconductor layer 74. The third peripheral electrode 75 may be formed from, for example, a material that forms a Schottky junction with the nitride semiconductor layer 74. Therefore, the third peripheral electrode 75 and the nitride semiconductor layer 74 form a Schottky junction.

The third peripheral electrode 75 may include one or more metal layers. In an example, the third peripheral electrode 75 may include a first metal layer, which contacts the nitride semiconductor layer 74, and a second metal layer, which is arranged above the first metal layer. The first metal layer may be formed from a material that forms a Schottky junction with the nitride semiconductor layer 74. In an example, the first metal layer includes at least one of TiN, TaN, WN, TiSiN, TaSiN, WSi, and WSiN. In an example, the first metal layer includes TiN. In an example, the second metal layer includes Ti. In this manner, the third peripheral electrode 75 is formed from the same conductive material as the gate electrode 29.

In an example, a width WRA of the third peripheral electrode 75 is greater than the width WGA of the gate electrode 29. In an example, the width WRA of the third peripheral electrode 75 may be greater than or equal to two times the width WGA of the gate electrode 29. In an example, the width WRA of the third peripheral electrode 75 may be less than or equal to twenty-five times the width WGA of the gate electrode 29. In an example, the width WRA of the third peripheral electrode 75 is greater than the width WSA of the second peripheral electrode 72. In an example, the width WRA of the third peripheral electrode 75 may be greater than or equal to two times the width WSA of the second peripheral electrode 72. In an example, the width WRA of the third peripheral electrode 75 may be less than or equal to twenty-five times the width WSA of the second peripheral electrode 72.

The nitride semiconductor layer 74 and the third peripheral electrode 75 are both covered by the first insulating layer 31. Therefore, the first insulating layer 31 is located between the stack of the nitride semiconductor layer 74 and the third peripheral electrode 75 and the stack of the nitride semiconductor layer 71 and the second peripheral electrode 72. Further, the first insulating layer 31 is located between the first peripheral electrode 73 and the stack of the nitride semiconductor layer 74 and the third peripheral electrode 75.

### Method for Manufacturing the Nitride Semiconductor Device

The method for manufacturing the nitride semiconductor device 10 in accordance with the fourth embodiment differs from the first embodiment in that the nitride semiconductor layer 74 and the third peripheral electrode 75 are additionally formed. The added steps will now be described.

As described above, the method for manufacturing the nitride semiconductor device 10 includes forming the nitride semiconductor layer 74. The nitride semiconductor layer 74, the gate layer 26, and the nitride semiconductor layer 71 are formed in the same step. As described above, the method for manufacturing the nitride semiconductor device 10 includes forming the third peripheral electrode 75. The third peripheral electrode 75, the gate electrode 29, and the second peripheral electrode 72 are formed in the same step.

The nitride semiconductor layer 801 shown in FIG. 12 forms the gate layer 26, the nitride semiconductor layer 71, and the nitride semiconductor layer 74. The electrode layer 802, which is formed above the nitride semiconductor layer 801, forms the gate electrode 29, the second peripheral electrode 72, and the third peripheral electrode 75. Lithography and etching are performed to sequentially remove the electrode layer 802 and the nitride semiconductor layer 801 in order to form the gate electrode 29, the second peripheral electrode 72, the third peripheral electrode 75, the gate layer 26, the nitride semiconductor layer 71, and the nitride semiconductor layer 74.

### Operation of Fourth Embodiment

The operation of the nitride semiconductor device 10 in accordance with the fourth embodiment will now be described. The nitride semiconductor device 10 is a normally-off type HEMT of which the gate threshold voltage is a positive value.

When a gate voltage Vgs is increased toward the negative side from a negative value of the gate threshold voltage of the transistors (transistor cells Tr1 to Tr4) of the cell region 11, current may flow from the source electrode 28 of the cell region 11 toward the first peripheral electrode 73.

In this respect, in the fourth embodiment, the nitride semiconductor layer 74, arranged between the nitride semiconductor layer 71 and the first peripheral electrode 73, depletes the 2DEG 25 between the nitride semiconductor layer 71 and the first peripheral electrode 73. This interrupts the flow of current from the source electrode 28 of the cell region 11 to the first peripheral electrode 73. Thus, the flow of current from the source electrode 28 of the cell region 11 to the first peripheral electrode 73 is limited.

The absolute value of ESD-induced surge current is sufficiently greater than the absolute value of the gate voltage Vgs. Therefore, with regard to the ESD-induced voltage between the gate and source, when negative voltage is applied to the gate electrode 29 and positive voltage is applied to the source electrode 28, surge current flows sequentially through the second peripheral electrode 72, the nitride semiconductor layer 71, and the 2DEG 25 to the first peripheral electrode 73. Alternatively, surge current flows from the source electrode 28, which is adjacent to the nitride semiconductor layer 71, through the 2DEG 25 to the first peripheral electrode 73. This limits the flow of surge current in the cell region 11.

In this manner, surge current flows from the second peripheral electrode 72 or the source electrode 28, which is adjacent to the nitride semiconductor layer 71, to the first peripheral electrode 73. During operation of the nitride semiconductor device 10, the flow of current from the source electrode 28 to the first peripheral electrode 73 is limited.

### Advantages of Fourth Embodiment

In addition to the advantages of the first embodiment, the nitride semiconductor device 10 in accordance with the fourth embodiment has the advantages described below.

(4-1) The nitride semiconductor device 10 includes the nitride semiconductor layer 74 including an acceptor impurity. The nitride semiconductor layer 74 is located between the nitride semiconductor layer 71 and the first peripheral electrode 73.

In this configuration, the nitride semiconductor layer 74 depletes the 2DEG 25 between the nitride semiconductor layer 71 and the first peripheral electrode 73. Therefore, even when the applied gate voltage Vgs is larger toward the negative side than the negative value of the gate threshold voltage, the flow of current from the source electrode 28 of the cell region 11 to the first peripheral electrode 73 is limited.

(4-2) If, for example, the nitride semiconductor layer 74 were to be electrically connected to the source electrode 28, the application of the gate voltage Vgs that is larger toward the negative side than the negative value of the gate threshold voltage would cause current to flow through the nitride semiconductor layer 74 to the first peripheral electrode 73.

In this respect, in the fourth embodiment, the nitride semiconductor layer 74 is in an electrically floating state. In this configuration, the 2DEG 25 underneath the nitride semiconductor layer 74 is depleted, and the flow of current from the nitride semiconductor layer 74 to the first peripheral electrode 73 is limited.

(4-3) The width WR of the nitride semiconductor layer 74 is greater than or equal to two times the width WG of the gate layer 26.

In this configuration, even when the applied gate voltage Vgs is larger toward the negative side than the negative value of the gate threshold voltage, the flow of current from the source electrode 28 of the cell region 11 to the first peripheral electrode 73 is limited.

(4-4) The width WR of the nitride semiconductor layer 74 is less than or equal to twenty-five times the width WG of the gate layer 26.

This configuration allows the nitride semiconductor device 10 to be reduced in size.

(4-5) The width WR of the nitride semiconductor layer 74 is between five times and fifteen times, inclusive, the width WG of the gate layer 26.

In this configuration, even when the applied gate voltage Vgs is larger toward the negative side than the negative value of the gate threshold voltage, the flow of current from the source electrode 28 of the cell region 11 to the first peripheral electrode 73 is further limited and the nitride semiconductor device 10 may be reduced in size.

(4-6) The nitride semiconductor layer 74, the nitride semiconductor layer 71, and the gate layer 26 are formed in the same step. The nitride semiconductor layer 74, the nitride semiconductor layer 71, and the gate layer 26 are equal in impurity concentration.

In this configuration, the nitride semiconductor layer 74, the nitride semiconductor layer 71, and the gate layer 26 are formed in the same step. Therefore, the dopant amount of the nitride semiconductor layer 74, the dopant amount of the nitride semiconductor layer 71, and the dopant amount of the gate layer 26 do not have to be changed. This simplifies the manufacturing process of the nitride semiconductor device 10.

(4-7) The gate electrode 29, the second peripheral electrode 72, and the third peripheral electrode 75 are formed in the same step. The gate electrode 29, the second peripheral electrode 72, and the third peripheral electrode 75 are formed from the same material.

In this configuration, the gate electrode 29, the second peripheral electrode 72, and the third peripheral electrode 75 are formed from the same material in the same step. This simplifies the manufacturing process of the nitride semiconductor device 10.

### Modified Examples

The above embodiments may be modified as described below. The above-described embodiments and the modified examples described below may be combined as long as there is technical consistency.

In each of the above embodiments, the peripheral isolation region 81 is not limited to the recess 81A and may have any configuration. In an example, as shown in FIG. 30, the peripheral isolation region 81 may include an inert region 93. More specifically, the electron transit layer 23 and the electron supply layer 24 include an active region 92 and the inert region 93, in which formation of the 2DEG 25 is more limited than in the active region 92. The inert region 93 extends through the electron supply layer 24 and at least part of the electron transit layer 23 in the Z-direction. Accordingly, the peripheral isolation region 81 extends over both the electron supply layer 24 and the electron transit layer 23 in the Z-direction. In the example shown in FIG. 30, the inert region 93 extends throughout the electron supply layer 24 in the Z-direction and extends over the entire electron transit layer 23 in the Z-direction. The inert region 93 may be formed by implanting ions. Examples of the type of implanted ions include hydrogen, boron, fluorine, and argon. In FIG. 30, the inert region 93 is shaded.

In the second and third embodiments, the element isolation region 82 is not limited to the recess 82A and may have any configuration. In an example, as shown in FIG. 30, the element isolation region 82 may include the inert region 93. Accordingly, the element isolation region 82 extends through both the electron supply layer 24 and the electron transit layer 23 in the Z-direction.

In each of the above embodiments, the dimension of the peripheral isolation region 81 in the Z-direction may be changed. In an example, the peripheral isolation region 81 may extend through both the electron supply layer 24 and the electron transit layer 23 in the Z-direction.

In the second and third embodiments, the dimension of the element isolation region 82 in the Z-direction may be changed. In an example, the element isolation region 82 may extend through the electron supply layer 24 and part of the electron transit layer 23 in the Z-direction. That is, the bottom surface of the recess 82A in the element isolation region 82 may be separated from the buffer layer 22 in the Z-direction.

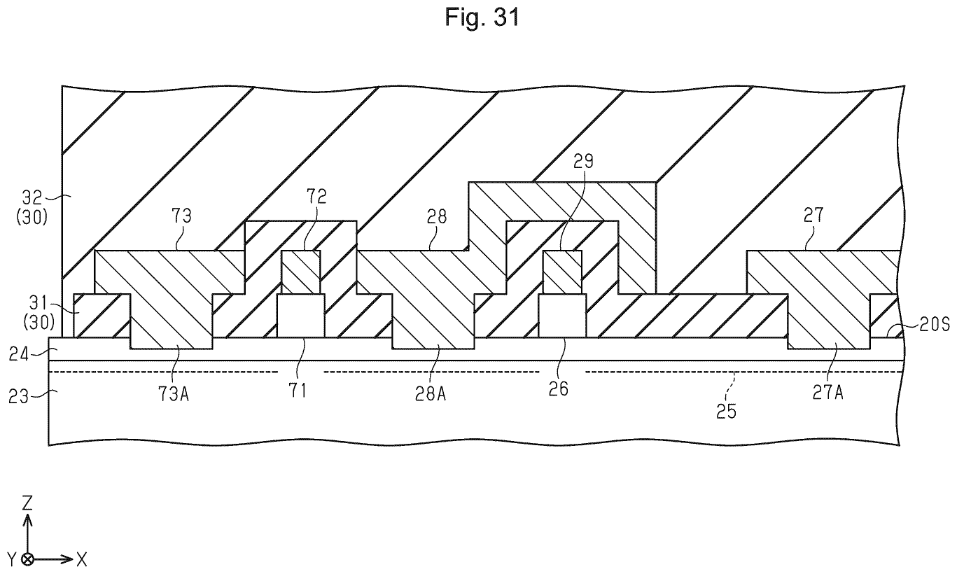

In each of the above embodiments, the structure for connecting the drain electrode 27, the source electrode 28, and the first peripheral electrode 73 to the electron supply layer 24 may be changed. In an example, as shown in FIG. 31, part of the first peripheral electrode 73 may extend into the electron supply layer 24 in the Z-direction. The source electrode 28 and the drain electrode 27 may both extend into the electron supply layer 24 in the Z-direction. In an example, when the nitride semiconductor device 10 is manufactured, thermal treatment is performed after forming the first peripheral electrode 73, the source electrode 28, and the drain electrode 27. This thermally diffuses and expands the contact portion 73A of the first peripheral electrode 73, the source contact 28A of the source electrode 28, and the drain contact 27A of the drain electrode 27 toward the electron supply layer 24. Accordingly, the contact portion 73A, the source contact 28A, and the drain contact 27A each extend into the electron supply layer 24. This configuration decreases the distance between the first peripheral electrode 73 and the 2DEG 25 in the Z-direction so that the surge current readily flows to the first peripheral electrode 73. Therefore, the ESD withstand capability of the nitride semiconductor device 10 can be increased. Further, the distance from the source contact 28A and the drain contact 27A to the 2DEG 25 is decreased. This reduces the on-resistance of the nitride semiconductor device 10.

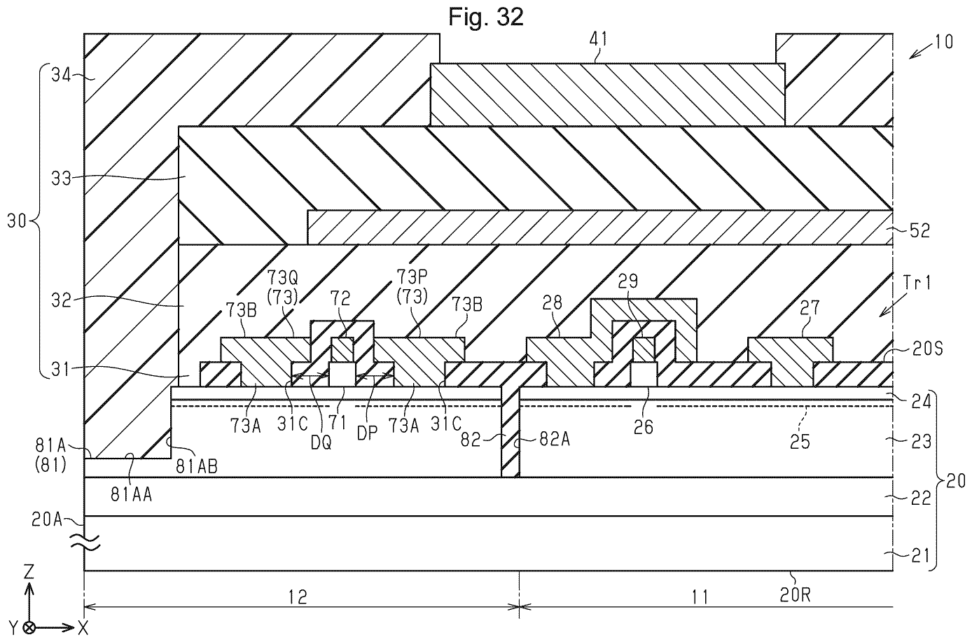

In each of the above embodiments, the first peripheral electrode 73 is not limited in number. In an example, more than one first peripheral electrode 73 is provided. For example, FIG. 32 shows a plurality of first peripheral electrodes 73 including a first electrode 73P and a second electrode 73Q. The first electrode 73P is located between the nitride semiconductor layer 71 and the cell region 11 in plan view. The second electrode 73Q is located closer to the edge of the peripheral region 12 than the nitride semiconductor layer 71 is in plan view. In an example, in plan view, distance DP between the first electrode 73P and the nitride semiconductor layer 71 is equal to distance DQ between the second electrode 73Q and the nitride semiconductor layer 71.

The first electrode 73P is looped and surrounds the cell region 11 in plan view. In an example, the first electrode 73P has the shape of a quadrilateral loop in plan view. In an example, the four corners of the first electrode 73P, which has the shape of a quadrilateral loop, are curved outward.

The nitride semiconductor layer 71 is looped and surrounds the first electrode 73P in plan view. In an example, the nitride semiconductor layer 71 has the shape of a quadrilateral loop in plan view. In an example, the four corners of the nitride semiconductor layer 71, which has the shape of a quadrilateral loop, are curved outward. The second peripheral electrode 72 is looped and surrounds the first electrode 73P in plan view. In an example, the second peripheral electrode 72 has the shape of a quadrilateral loop in plan view. In an example, the four corners of the looped second peripheral electrode 72, which has the shape of a quadrilateral loop, are curved outward.

The second electrode 73Q is looped and surrounds the nitride semiconductor layer 71 in plan view. In an example, the second electrode 73Q has the shape of a quadrilateral loop in plan view. In an example, the four corners of the second electrode 73Q, which has the shape of a quadrilateral loop, are curved outward. The second electrode 73Q is looped and surrounds the second peripheral electrode 72 in plan view.

The nitride semiconductor device 10 further includes the element isolation region 82 located between the first electrode 73P and the cell region 11. The element isolation region 82 is looped and surrounds the cell region 11 in plan view. In an example, the element isolation region 82 has the shape of a quadrilateral loop in plan view. More specifically, the four corners of the element isolation region 82, which has the shape of a quadrilateral loop, are curved outward. The element isolation region 82 includes the recess 82A. The recess 82A has the same shape and size as the recess 82A of the second embodiment.

Although not shown in the drawings, the first electrode 73P is electrically connected to the gate wiring 53 by first peripheral vias. The second electrode 73Q is electrically connected to the gate wiring 53 by second peripheral vias. The first peripheral vias and the second peripheral vias are each formed from the same material and have the same configuration as the first peripheral vias 68 (refer to FIG. 9). In this manner, the first electrode 73P and the second electrode 73Q are electrically connected to the gate electrode 29.

In this configuration, surge current that flows through the second peripheral electrode 72 flows through the nitride semiconductor layer 71 and the 2DEG 25 to both the first electrode 73P and the second electrode 73Q. In this manner, the current paths through which current flows are increased in number. This allows surge current to readily flow from the source electrode 28 to the gate electrode 29. Therefore, the ESD withstand capability of the nitride semiconductor device 10 can be increased.

The first electrode 73P and the second electrode 73Q may be located at any position. In an example, the electrodes 73P and 73Q may be located closer to the cell region 11 than the nitride semiconductor layer 71 is in plan view. That is, the electrodes 73P and 73Q may be located between the nitride semiconductor layer 71 and the element isolation region 82 in plan view. In another example, the electrodes 73P and 73Q may be located closer to the edges of the semiconductor layer 20 than the nitride semiconductor layer 71 is in plan view. That is, the electrodes 73P and 73Q may be located between the nitride semiconductor layer 71 and the peripheral isolation region 81 in plan view. Further, the first electrode 73P or the second electrode 73Q may have the shape of an open loop in plan view.

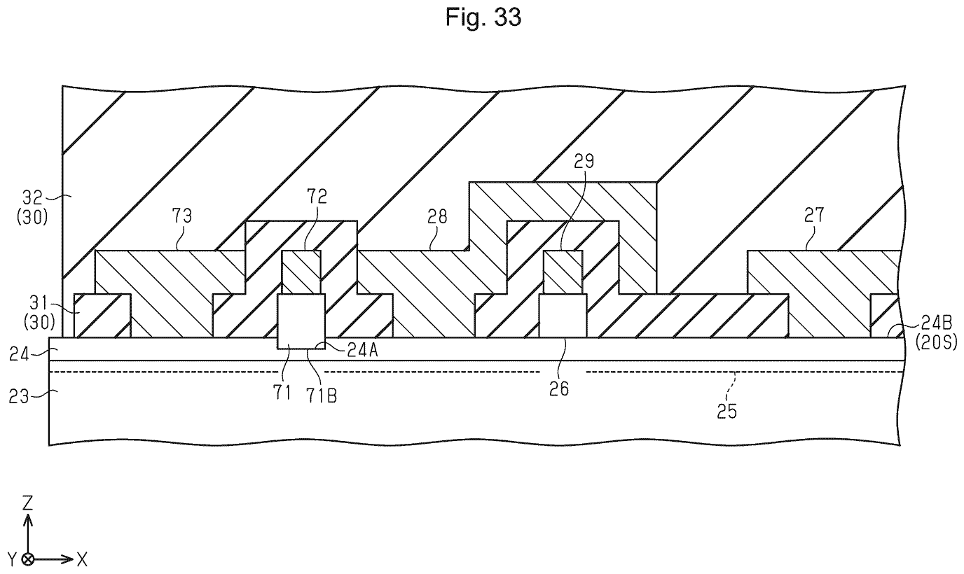

In the first and second embodiments, the structure connecting the nitride semiconductor layer 71 and the electron supply layer 24 may be changed. In an example, as shown in FIG. 33, the electron supply layer 24 includes a trench 24A. The nitride semiconductor layer 71 is arranged in the trench 24A. The trench 24A may be looped to surround the cell region 11 in plan view. The nitride semiconductor layer 71 extends into the trench 24A. Therefore, a lower surface 71B of the nitride semiconductor layer 71 is located closer to the electron transit layer 23 (2DEG 25) than an upper surface 24B of the electron supply layer 24 is. The upper surface 24B of the electron supply layer 24 defines the first surface 20S of the semiconductor layer 20. Therefore, the lower surface 71B of the nitride semiconductor layer 71 is located closer to the electron transit layer 23 (2DEG 25) than the first surface 20S of the semiconductor layer 20 is.

This configuration decreases the distance between the nitride semiconductor layer 71 and the 2DEG 25 so that surge current readily flows from the second peripheral electrode 72 through the nitride semiconductor layer 71 and the 2DEG 25 to the first peripheral electrode 73. Therefore, the ESD withstand capability of the nitride semiconductor device 10 can be increased. Although not shown in the drawings, the structure connecting the gate layer 26 and the electron supply layer 24 may be changed in the same manner as the structure connecting the nitride semiconductor layer 71 and the electron supply layer 24.

In each of the above embodiments, the source field plate 28C may be omitted from the source electrode 28.

In the first and second embodiments, the nitride semiconductor layer 71 may have any shape in plan view. In an example, the nitride semiconductor layer 71 may have the shape of an elliptical loop, an oval loop, a circular loop, or a polygonal loop other than a quadrilateral loop in plan view. The nitride semiconductor layer 71 may have the shape of a loop that is partially discontinuous in plan view. In another example, the nitride semiconductor layer 71 does not have to be loop-shaped in plan view.

In the first and second embodiments, the second peripheral electrode 72 may have any shape in plan view. In an example, the second peripheral electrode 72 may have the shape of an elliptical loop, an oval loop, a circular loop, or a polygonal loop other than a quadrilateral loop in plan view. The second peripheral electrode 72 may have the shape of a loop that is partially discontinuous in plan view. In another example, the second peripheral electrode 72 does not have to be loop-shaped in plan view.

In the second and third embodiments, the element isolation region 82 may have any shape in plan view. In an example, the element isolation region 82 may have the shape of an elliptical loop, an oval loop, a circular loop, or a polygonal loop other than a quadrilateral loop in plan view. The element isolation region 82 may have the shape of a loop that is partially discontinuous in plan view. In another example, the element isolation region 82 does not have to be loop-shaped in plan view.

In each of the above embodiments, the first peripheral electrode 73 may have any shape in plan view. In an example, the first peripheral electrode 73 may have the shape of an elliptical loop, an oval loop, a circular loop, or a polygonal loop other than a quadrilateral loop in plan view. The first peripheral electrode 73 may have the shape of a loop that is partially discontinuous in plan view. In another example, the first peripheral electrode 73 does not have to be loop-shaped in plan view.

In each of the above embodiments, the peripheral isolation region 81 may have any shape in plan view. In an example, the peripheral isolation region 81 may have the shape of an elliptical loop, an oval loop, a circular loop, or a polygonal loop other than a quadrilateral loop in plan view. The peripheral isolation region 81 may have the shape of a loop that is partially discontinuous in plan view. In another example, the peripheral isolation region 81 does not have to be loop-shaped in plan view.

In each of the above embodiments, the width WA of the peripheral isolation region 81 may be less than or equal to the width WB of the element isolation region 82.

In the first embodiment, the element isolation region 82 may be located between the nitride semiconductor layer 71 and the cell region 11. This further limits the flow of surge current to the cell region 11 when surge current flows from the second peripheral electrode 72 to the nitride semiconductor layer 71 and the 2DEG 25.

In the second and third embodiments, the element isolation region 82 may be omitted.

In the first and second embodiments, the gate electrode 29 and the second peripheral electrode 72 may be formed from different conductive materials.

In each of the above embodiments, the source electrode 28, the drain electrode 27, and the first peripheral electrode 73 may be formed from different conductive materials.

In the third embodiment, the structure electrically connecting the source electrode 28 to the semiconductor substrate 21 is not limited to the vias 91 and may be changed. In an example, a wiring member (e.g., wire) arranged outside the nitride semiconductor device 10 may electrically connect the source pad 42 and the semiconductor substrate 21. This electrically connects the source electrode 28 to the semiconductor substrate 21 through the source pad 42.

In each of the above embodiments, the width WGB of the gate wiring 53 may be less than or equal to the width WGA of the gate electrode 29.

In each of the above embodiments, a further conductive layer may be located between the first peripheral electrode 73 and the electron supply layer 24. The first peripheral electrode 73 may be electrically connected to the electron supply layer 24 by the conductive layer.

In the fourth embodiment, the third peripheral electrode 75 may be omitted.

In the fourth embodiment, the nitride semiconductor layer 74 is not limited in number. One or more nitride semiconductor layers 74 may be arranged between the first peripheral electrode 73 and the nitride semiconductor layer 71.

In the fourth embodiment, the nitride semiconductor layer 74 may be located at any position in the Z-direction. In an example, the nitride semiconductor layer 74 may be located at a position differing from the nitride semiconductor layer 71 in the Z-direction. In another example, the lower surface of the nitride semiconductor layer 74 may be located closer to the electron transit layer 23 (2DEG 25) than the upper surface 24B of the electron supply layer 24 is in the Z-direction. In this case, the lower surface of the nitride semiconductor layer 71 is also located closer to the electron transit layer 23 (2DEG 25) than the upper surface 24B of the electron supply layer 24 is in the Z-direction.

In the fourth embodiment, the width WR of the nitride semiconductor layer 74 may be changed. In an example, the width WR of the nitride semiconductor layer 74 may be less than or equal to the width WG of the gate layer 26. In an example, the width WR of the nitride semiconductor layer 74 may be greater than twenty-five times the width WG of the gate layer 26.

In the fourth embodiment, the first peripheral electrode 73 may be located closer to the cell region 11 than the nitride semiconductor layer 71 is in the same manner as the modified example shown in FIG. 30. In this case, the nitride semiconductor layer 74 is located between the first peripheral electrode 73 and the nitride semiconductor layer 71.

In this specification, the word “above” includes the meaning of “on” in addition to the meaning of “above” unless otherwise described in the context. Accordingly, for example, the expression of “first element arranged above second element” may mean that the first element is arranged directly on the second element in one embodiment and mean that the first element is arranged above the second element without contacting the second element in another embodiment. Thus, the word “above” will also allow for a structure in which another element is formed between the first element and the second element.

The Z-direction as referred to in this specification does not necessarily have to be the vertical direction and does not necessarily have to exactly coincide with the vertical direction. Accordingly, in the structures of the present disclosure, “up” and “down” in the Z-direction as referred to in this specification is not limited to “up” and “down” in the vertical direction. For example, the X-direction may be the vertical direction. Alternatively, the Y-direction may be the vertical direction.

### CLAUSES

Technical concepts that can be understood from the present disclosure will now be described. Reference characters used in the above embodiments are added to corresponding elements in the clauses to aid understanding without any intention to impose limitations to these elements. The reference characters are given as examples to aid understanding and not intended to limit elements to the elements denoted by the reference characters.

### Clause 1

A nitride semiconductor device (10), including:
a semiconductor substrate (21);
an electron transit layer (23) located above the semiconductor substrate (21);
an electron supply layer (24) located above the electron transit layer (23) and having a larger band gap than the electron transit layer (23);
a gate layer (26) formed from a nitride semiconductor including an acceptor impurity and located above a part of the electron supply layer (24);
a gate electrode (29) located above the gate layer (26);
a source electrode (28) and a drain electrode (27) located above the electron supply layer (24) and separated from each other;
a cell region (11) in which a transistor, including the gate electrode (29), the source electrode (28), and the drain electrode (27), is arranged;
a peripheral region (12) surrounding the cell region (11), as viewed in a thickness direction (Z) of the semiconductor substrate (21);
a nitride semiconductor layer (71) formed from a nitride semiconductor including an acceptor impurity and located in the peripheral region (12);
a second peripheral electrode (72) located above the nitride semiconductor layer (71); and
a first peripheral electrode (73) located in the peripheral region (12), where
the first peripheral electrode (73) is electrically connected to the gate electrode (29), and
the second peripheral electrode (72) is electrically connected to the source electrode (28).

### Clause 2

The nitride semiconductor device according to clause 1, where: the nitride semiconductor layer (71) is located closer to the cell region (11) than the first peripheral electrode (73) is, as viewed in the thickness direction (Z) of the semiconductor substrate (21); and the nitride semiconductor layer (71) is electrically connected to the transistor in the cell region (11) by a two-dimensional electron gas (25).

### Clause 3

The nitride semiconductor device according to clause 1 or 2, where the nitride semiconductor layer (71) is looped, as viewed in the thickness direction (Z) of the semiconductor substrate (21).

### Clause 4

The nitride semiconductor device according to any one of clauses 1 to 3, where the first peripheral electrode (73) is looped and surrounds the nitride semiconductor layer (71) and the second peripheral electrode (72), as viewed in the thickness direction (Z) of the semiconductor substrate (21).

### Clause 5

The nitride semiconductor device according to clause 1, further including:
an element isolation region (82) located between the cell region (11) and the peripheral region (12) and electrically isolating the cell region (11) from the peripheral region (12), where
the first peripheral electrode (73) is located closer to the cell region (11) than the second peripheral electrode (72) is, as viewed in the thickness direction (Z) of the semiconductor substrate (21), and
the element isolation region (82) is located between the first peripheral electrode (73) and the cell region (11).

### Clause 6

The nitride semiconductor device according to clause 5, where the element isolation region (82) includes a recess (82A) extending through the electron supply layer (24) and at least a part of the electron transit layer (23) in the thickness direction (Z) of the semiconductor substrate (21).

### Clause 7

The nitride semiconductor device according to clause 5 or 6, where:
the element isolation region (82) is looped and surrounds the cell region (11), as viewed in the thickness direction (Z) of the semiconductor substrate (21); and
the first peripheral electrode (73) is looped and surrounds the element isolation region (82), as viewed in the thickness direction (Z) of the semiconductor substrate (21).

### Clause 8

The nitride semiconductor device according to any one of clauses 5 to 7, where the nitride semiconductor layer (71) is looped and surrounds the first peripheral electrode (73) as viewed in the thickness direction (Z) of the semiconductor substrate (21).

### Clause 9

The nitride semiconductor device according to any one of clauses 1 to 8, where the gate electrode (29) and the second peripheral electrode (72) are formed from the same conductive material.

### Clause 10

The nitride semiconductor device according to any one of clauses 1 to 9, further including:
a first insulating layer (31) covering the gate electrode (29) and the second peripheral electrode (72);
a second insulating layer (32) located above the first insulating layer (31) and covering the source electrode (28) and the drain electrode (27);
gate wiring (53) and source wiring (52) located above the second insulating layer (32);
a gate via (63) connecting the gate wiring (53) and the gate electrode (29);
a first peripheral via (68) connecting the gate wiring (53) and the first peripheral electrode (73);
a source via (62) connecting the source wiring (52) and the source electrode (28); and
a second peripheral via (67) connecting the source wiring (52) and the second peripheral electrode (72).

### Clause 11

A nitride semiconductor device (10), including:
a semiconductor substrate (21);
an electron transit layer (23) located above the semiconductor substrate (21);
an electron supply layer (24) located above the electron transit layer (23) and having a larger band gap than the electron transit layer (23);
a gate layer (26) formed from a nitride semiconductor including an acceptor impurity and located above a part of the electron supply layer (24);
a gate electrode (29) located above the gate layer (26);
a source electrode (28) and a drain electrode (27) located above the electron supply layer (24) and separated from each other;
a cell region (11) in which a transistor, including the gate electrode (29), the source electrode (28), and the drain electrode (27), is arranged;
a peripheral region (12) surrounding the cell region (11), as viewed in a thickness direction (Z) of the semiconductor substrate (21);
an element isolation region (82) located between the cell region (11) and the peripheral region (12) and electrically isolating the cell region (11) from the peripheral region (12); and
a first peripheral electrode (73) located in the peripheral region (12), where
the semiconductor substrate (21) is electrically connected to the source electrode (28), and
the first peripheral electrode (73) is electrically connected to the gate electrode (29).

### Clause 12

The nitride semiconductor device according to clause 11, where the element isolation region (82) includes a recess (82A) extending through the electron supply layer (24) and at least a part of the electron transit layer (23) in the thickness direction (Z) of the semiconductor substrate (21).

### Clause 13

The nitride semiconductor device according to clause 11 or 12, where the element isolation region (82) extends throughout the electron transit layer (23) in the thickness direction (Z).

### Clause 14

The nitride semiconductor device according to any one of clauses 11 to 13, where
the element isolation region (82) is looped and surrounds the cell region (11), as viewed in the thickness direction (Z) of the semiconductor substrate (21); and
the first peripheral electrode (73) is looped and surrounds the element isolation region (82), as viewed in the thickness direction (Z) of the semiconductor substrate (21).

### Clause 15

The nitride semiconductor device according to any one of clauses 1 to 14, where a total length of the first peripheral electrode (73) is between 1% and 40%, inclusive, of a total length of the gate electrode (29).

### Clause 16

The nitride semiconductor device according to any one of clauses 1 to 14, where a total length of the first peripheral electrode (73) is between 5% and 20%, inclusive, of a total length of the gate electrode (29).

### Clause 17

The nitride semiconductor device according to any one of clauses 1 to 16, where the gate layer (26) has an impurity concentration between 1×10¹⁸ cm⁻³ and 1×10¹⁹ cm⁻³, inclusive.

### Clause 18

The nitride semiconductor device according to any one of clauses 1 to 16, where the gate layer (26) has an impurity concentration between 2×10¹⁸ cm⁻³ and 5×10¹⁸ cm⁻³, inclusive.

### Clause 19

The nitride semiconductor device according to any one of clauses 1 to 18, where:
the nitride semiconductor layer (71) defines a first nitride semiconductor layer;
the nitride semiconductor device further includes a second nitride semiconductor layer (74) formed from a nitride semiconductor including an acceptor impurity; and
the second nitride semiconductor layer (74) is located between the first peripheral electrode (73) and the first nitride semiconductor layer (71).

### Clause 20

The nitride semiconductor device according to clause 19, where the second nitride semiconductor layer (74) is in an electrically floating state.

### Clause 21

The nitride semiconductor device according to clause 19 or 20, where a width (WR) of the second nitride semiconductor layer (74) is two times or greater than a width (WG) of the gate layer (26).

### Clause 22

The nitride semiconductor device according to any one of clauses 19 to 21, where a width (WR) of the second nitride semiconductor layer (74) is less than or equal to twenty-five times a width (WG) of the gate layer (26).

### Clause 23

The nitride semiconductor device according to clause 19 or 20, where a width (WR) of the second nitride semiconductor layer (74) is between five times and fifteen times, inclusive, a width (WG) of the gate layer (26).

### Clause 24

The nitride semiconductor device according to any one of clauses 19 to 23, where the second nitride semiconductor layer (74) and the gate layer (26) are equal in impurity concentration.

### Clause 25

The nitride semiconductor device according to any one of clauses 19 to 24, further including a third peripheral electrode (75) located above the second nitride semiconductor layer (74).

### Clause 26

The nitride semiconductor device according to any one of clauses 1 to 16, where the gate layer (26) has an impurity concentration between 2×10¹⁸ cm⁻³ and 5×10¹⁸ cm⁻³.

### Clause 27

The nitride semiconductor device according to any one of clauses 1 to 26, where the source electrode (28), the drain electrode (27), and the first peripheral electrode (73) are formed from the same conductive material.

### Clause 28

The nitride semiconductor device according to any one of clauses 1 to 27, where the gate electrode (29) and the gate layer (26) form a Schottky junction.

### Clause 29

The nitride semiconductor device according to clause 3, where the second peripheral electrode (72) is looped, as viewed in the thickness direction (Z) of the semiconductor substrate (21).

### Clause 30

The nitride semiconductor device according to clause 5 or 11, where:
the electron transit layer (23) and the electron supply layer (24) include an active region (92), and
an inert region (93) in which formation of a two-dimensional electron gas (25) is more limited than in the active region (92);
the element isolation region (82) extends over both the electron supply layer (24) and the electron transit layer (23) in the thickness direction (Z) of the semiconductor substrate (21); and
the element isolation region (82) includes the inert region (93).

### Clause 31

The nitride semiconductor device according to any one of clauses 11 to 14, further including:
a via (91) electrically connecting the source electrode (28) and the semiconductor substrate (21) in the thickness direction (Z) of the semiconductor substrate (21),
where the via (91) extends through both the electron supply layer (24) and the electron transit layer (23) in the cell region (11).

### Clause 32

The nitride semiconductor device according to any one of clauses 11 to 14, further including:
an insulating layer (32) covering the gate electrode (29) and the first peripheral electrode (73);
gate wiring (53) located above the insulating layer (31);
a gate via (63) connecting the gate wiring (53) and the gate electrode (29); and
a first peripheral via (68) connecting the gate wiring (53) and the first peripheral electrode (73).

### Clause 33

The nitride semiconductor device according to clause 32, where a width (WGB) of the gate wiring (53) is greater than a width (WGA) of the gate electrode (29).

### Clause 34

The nitride semiconductor device according to any one of clauses 1 to 33, where the first peripheral electrode (73) is in contact with the electron supply layer (24).

### Clause 35

The nitride semiconductor device according to any one of clauses 1 to 34, further including:
a peripheral isolation region (81) including an edge of the peripheral region (12),
where the peripheral isolation region (81) is looped and surrounds the first peripheral electrode (73), as viewed in a thickness direction (Z) of the semiconductor substrate (21).

### Clause 36

The nitride semiconductor device according to clause 35, where the peripheral isolation region (81) includes a recess (81A) extending through the electron supply layer (24) and at least part of the electron transit layer (23) in the thickness direction (Z) of the semiconductor substrate (21).

### Clause 37

The nitride semiconductor device according to clause 35, where:
the electron transit layer (23) and the electron supply layer (24) include an active region (92), and
an inert region (93) in which formation of a two-dimensional electron gas (25) is more limited than in the active region (92);
the peripheral isolation region (81) extends over both the electron supply layer (24) and the electron transit layer (23) in the thickness direction (Z) of the semiconductor substrate (21); and
the peripheral isolation region (81) includes the inert region (93).

### Clause 38

The nitride semiconductor device according to any one of clauses 11 to 14, further including:
a peripheral isolation region (81) including an edge of the peripheral region (12), where
the peripheral isolation region (81) is looped and surrounds the first peripheral electrode (73), as viewed in the thickness direction (Z) of the semiconductor substrate (21), and
a width (WA) of the peripheral isolation region (81) is greater than a width (WB) of the element isolation region (82).

### Clause 39

The nitride semiconductor device according to any one of clauses 1 to 10, where the nitride semiconductor layer (71) and the gate layer (26) are equal in impurity concentration.

### Clause 40

The nitride semiconductor device according to any one of clauses 1 to 39, where a portion of the gate electrode (29) that contacts the gate layer (26) includes at least one of TiN, TaN, WN, TiSiN, TaSiN, WSi, and WSiN.

### Clause 41

The nitride semiconductor device according to any one of clauses 1 to 40, wherein the first peripheral electrode (73) is one of a plurality of first peripheral electrodes (73).

### Clause 42

The nitride semiconductor device according to any one of clauses 1 to 10, where:
the first peripheral electrode (73) includes a first electrode (73P) and a second electrode (73Q);
the first electrode (73P) is located between the nitride semiconductor layer (71) and the cell region (11), as viewed in the thickness direction (Z) of the semiconductor substrate (21);
the second electrode (73Q) is located closer to an edge of the peripheral region (12) than the nitride semiconductor layer (71) is, as viewed in a thickness direction (Z) of the semiconductor substrate (21).

### Clause 43

The nitride semiconductor device according to clause 42, where:
the first electrode (73P) is looped and surrounds the cell region (11), as viewed in the thickness direction (Z) of the semiconductor substrate (21);
the nitride semiconductor layer (71) is looped and surrounds the first electrode (73P), as viewed in the thickness direction (Z) of the semiconductor substrate (21); and
the second electrode (73Q) is looped and surrounds the nitride semiconductor layer (71), as viewed in the thickness direction (Z) of the semiconductor substrate (21).

### Clause 44

The nitride semiconductor device according to clause 42 or 43, further including:
an element isolation region (82) located between the first electrode (73P) and the cell region (11),
where the element isolation region (82) is looped and surrounds the cell region (11), as viewed in a thickness direction (Z) of the semiconductor substrate (21).

### Clause 45

The nitride semiconductor device according to any one of clauses 1 to 44, where a part of the first peripheral electrode (73) extends into the electron supply layer (24) in the thickness direction (Z) of the semiconductor substrate (21).

### Clause 46

The nitride semiconductor device according to clause 45, where the source electrode (28) and the drain electrode (27) both extend into the electron supply layer (24) in the thickness direction (Z) of the semiconductor substrate (21).

### clause 47

The nitride semiconductor device according to any one of clauses 1 to 10, where:
the electron supply layer (24) includes a trench (24A); and
the nitride semiconductor layer (26) is located in the trench (24A).

### Clause 48

The nitride semiconductor device according to any one of clauses 1 to 10, where a width (WGC) of the first peripheral electrode (73) is greater than a width (WSA) of the second peripheral electrode (72).

### Clause 49

A method for manufacturing a nitride semiconductor device (10), the method comprising:
forming an electron transit layer (23) above a semiconductor substrate (21);
forming an electron supply layer (24), having a larger band gap than the electron transit layer (23), above the electron transit layer (23);
forming a gate layer (26), from a nitride semiconductor including an acceptor impurity, above a part of the electron supply layer (24);
forming a gate electrode (29) above the gate layer (26);
forming a source electrode (28) and a drain electrode (27), separated from each other, above the electron supply layer (24), where the nitride semiconductor device (10) includes
a cell region (11) in which a transistor, including the gate electrode (29), the source electrode (28), and the drain electrode (27), is arranged, and
a peripheral region (12) surrounding the cell region (11), as viewed in a thickness direction (Z) of the semiconductor substrate (21);
forming a nitride semiconductor layer (71), from a nitride semiconductor including an acceptor impurity, in the peripheral region (12) above the electron supply layer (24);
forming a second peripheral electrode (72), electrically connected to the source electrode (28), above the nitride semiconductor layer (71); and
forming a first peripheral electrode (73), electrically connected to the gate electrode (29), in the peripheral region (12).

### Clause 50

The method according to clause 49, where:
the forming the nitride semiconductor layer (71) and the forming the gate layer (26) are performed together; and
the nitride semiconductor layer (71) and the gate layer (26) are equal in impurity concentration.

### Clause 51

The method according to clause 49 or 50, where
the forming the gate electrode (29) and the forming the second peripheral electrode (72) are performed together;
the gate electrode (29) and the second peripheral electrode (72) are formed from the same material.

### Clause 52

The method according to any one of clauses 49 to 51, where:
the forming the drain electrode (27), the forming the source electrode (28), and the forming the first peripheral electrode (73) are performed together; and
the drain electrode (27), the source electrode (28), and the first peripheral electrode (73) are formed from the same material.

### Clause 53

The method according to clause 49, where:
the nitride semiconductor layer (71) defines a first nitride semiconductor layer;
the method further includes forming a second nitride semiconductor layer (74), from a nitride semiconductor including an acceptor impurity, above the electron supply layer (24) between the first peripheral electrode (73) and the first nitride semiconductor layer (71).

### Clause 54

The method according to clause 53, where:
the forming the second nitride semiconductor layer (74), the forming the first nitride semiconductor layer (71), and the forming the gate layer (26) are performed together; and
the second nitride semiconductor layer (74), the first nitride semiconductor layer (71), and the gate layer (26) are equal in impurity concentration.

### Clause 55

The method according to clause 53 or 54, further including forming a third peripheral electrode (75) above the second nitride semiconductor layer (74).

### Clause 56

The method according to clause 55, where:
the forming the gate electrode (29), the forming the second peripheral electrode (72), and the forming the third peripheral electrode (75) are performed together; and
the gate electrode (29), the second peripheral electrode (72), and the third peripheral electrode (75) are formed from the same material.

### Clause 57

A method for manufacturing a nitride semiconductor device (10), the method comprising:
forming an electron transit layer (23) above a semiconductor substrate (21);
forming an electron supply layer (24), having a larger band gap than the electron transit layer (23), above the electron transit layer (23);
forming a gate layer (26), from a nitride semiconductor including an acceptor impurity, above a part of the electron supply layer (24);
forming a gate electrode (29) above the gate layer (26);
forming a source electrode (28) and a drain electrode (27), separated from each other, above the electron supply layer (24),
where the nitride semiconductor device (10) includes
a cell region (11) in which a transistor, including the gate electrode (29), the source electrode (28), and the drain electrode (27), is arranged, and
a peripheral region (12) surrounding the cell region (11), as viewed in a thickness direction (Z) of the semiconductor substrate (21);
forming an element isolation region (82), electrically isolating the cell region (11) and the peripheral region (12), between the cell region (11) and the peripheral region (12);
forming a first peripheral electrode (73), electrically connected to the gate electrode (29), in the peripheral region (12); and
electrically connecting the source electrode (28) to the semiconductor substrate (21).

### Clause 58

The method according to clause 57, where the forming the element isolation region (82) includes forming the element isolation region (82) by performing etching.

### Clause 59

The method according to clause 57 or 58, where:
forming the source electrode (28) and the drain electrode (27) and forming the first peripheral electrode (73) are performed together; and
the source electrode (28), the drain electrode (27), and the first peripheral electrode (73) are formed from the same material.

### Clause 60

The method according to any one of clauses 57 to 59, further including forming a via (91) connecting the source electrode (28) and the semiconductor substrate (21).

Various changes in form and details may be made to the examples above without departing from the spirit and scope of the claims and their equivalents. The examples are for the sake of description only, and not for purposes of limitation. Descriptions of features in each example are to be considered as being applicable to similar features or aspects in other examples. Suitable results may be achieved if sequences are performed in a different order, and/or if components in a described system, architecture, device, or circuit are combined differently, and/or replaced or supplemented by other components or their equivalents. The scope of the disclosure is not defined by the detailed description, but by the claims and their equivalents. All variations within the scope of the claims and their equivalents are included in the disclosure.

1. A nitride semiconductor device, comprising:
a semiconductor substrate;
an electron transit layer located above the semiconductor substrate;
an electron supply layer located above the electron transit layer and having a larger band gap than the electron transit layer;
a gate layer formed from a nitride semiconductor including an acceptor impurity and located above a part of the electron supply layer;
a gate electrode located above the gate layer;
a source electrode and a drain electrode located above the electron supply layer and separated from each other;
a cell region in which a transistor, including the gate electrode, the source electrode, and the drain electrode, is arranged;
a peripheral region surrounding the cell region, as viewed in a thickness direction of the semiconductor substrate;
a nitride semiconductor layer formed from a nitride semiconductor including an acceptor impurity and located in the peripheral region;
a second peripheral electrode located above the nitride semiconductor layer; and
a first peripheral electrode located in the peripheral region, wherein
the first peripheral electrode is electrically connected to the gate electrode, and
the second peripheral electrode is electrically connected to the source electrode.

2. The nitride semiconductor device according to claim 1, wherein the nitride semiconductor layer is located closer to the cell region than the first peripheral electrode is, as viewed in the thickness direction of the semiconductor substrate, and the nitride semiconductor layer is electrically connected to the transistor in the cell region by a two-dimensional electron gas.

3. The nitride semiconductor device according to claim 1, wherein the nitride semiconductor layer is looped, as viewed in the thickness direction of the semiconductor substrate.

4. The nitride semiconductor device according to claim 1, wherein the first peripheral electrode is looped and surrounds the nitride semiconductor layer and the second peripheral electrode, as viewed in the thickness direction of the semiconductor substrate.

5. The nitride semiconductor device according to claim 1, further comprising:
an element isolation region located between the cell region and the peripheral region and electrically isolating the cell region from the peripheral region, wherein
the first peripheral electrode is located closer to the cell region than the second peripheral electrode is, as viewed in the thickness direction of the semiconductor substrate, and
the element isolation region is located between the first peripheral electrode and the cell region.

6. The nitride semiconductor device according to claim 5, wherein the element isolation region includes a recess extending through the electron supply layer and at least a part of the electron transit layer in the thickness direction of the semiconductor substrate.

7. The nitride semiconductor device according to claim 5, wherein:
the element isolation region is looped and surrounds the cell region, as viewed in the thickness direction of the semiconductor substrate; and
the first peripheral electrode is looped and surrounds the element isolation region, as viewed in the thickness direction of the semiconductor substrate.

8. The nitride semiconductor device according to claim 5, wherein the nitride semiconductor layer is looped and surrounds the first peripheral electrode, as viewed in the thickness direction of the semiconductor substrate.

9. The nitride semiconductor device according to claim 1, wherein the gate electrode and the second peripheral electrode are formed from the same conductive material.

10. The nitride semiconductor device according to claim 1, further comprising:
a first insulating layer covering the gate electrode and the second peripheral electrode;
a second insulating layer located above the first insulating layer and covering the source electrode and the drain electrode;
gate wiring and source wiring located above the second insulating layer;
a gate via connecting the gate wiring and the gate electrode;
a first peripheral via connecting the gate wiring and the first peripheral electrode;
a source via connecting the source wiring and the source electrode; and
a second peripheral via connecting the source wiring and the second peripheral electrode.

11. A nitride semiconductor device, comprising:
a semiconductor substrate;
an electron transit layer located above the semiconductor substrate;
an electron supply layer located above the electron transit layer and having a larger band gap than the electron transit layer;
a gate layer formed from a nitride semiconductor including an acceptor impurity and located above a part of the electron supply layer;
a gate electrode located above the gate layer;
a source electrode and a drain electrode located above the electron supply layer and separated from each other;
a cell region in which a transistor, including the gate electrode, the source electrode, and the drain electrode, is arranged;
a peripheral region surrounding the cell region, as viewed in a thickness direction of the semiconductor substrate;
an element isolation region located between the cell region and the peripheral region and electrically isolating the cell region from the peripheral region; and
a first peripheral electrode located in the peripheral region, wherein
the semiconductor substrate is electrically connected to the source electrode, and
the first peripheral electrode is electrically connected to the gate electrode.

12. The nitride semiconductor device according to claim 11, wherein the element isolation region includes a recess extending through the electron supply layer and at least a part of the electron transit layer in the thickness direction of the semiconductor substrate.

13. The nitride semiconductor device according to claim 11, wherein the element isolation region extends throughout the electron transit layer in the thickness direction.

14. The nitride semiconductor device according to claim 11, wherein:
the element isolation region is looped and surrounds the cell region, as viewed in the thickness direction of the semiconductor substrate; and
the first peripheral electrode is looped and surrounds the element isolation region, as viewed in the thickness direction of the semiconductor substrate.

15. The nitride semiconductor device according to claim 1, wherein a total length of the first peripheral electrode is between 1% and 40%, inclusive, of a total length of the gate electrode.

16. The nitride semiconductor device according to claim 1, wherein a total length of the first peripheral electrode is between 5% and 20%, inclusive, of a total length of the gate electrode.

17. The nitride semiconductor device according to claim 1, wherein the gate layer has an impurity concentration between 1×10¹⁸ cm⁻³ and 1×10¹⁹ cm⁻³, inclusive.

18. The nitride semiconductor device according to claim 1, wherein the gate layer has an impurity concentration between 2×10¹⁸ cm⁻³ and 5×10¹⁸ cm⁻³, inclusive.

19. The nitride semiconductor device according to claim 1, wherein:
the nitride semiconductor layer defines a first nitride semiconductor layer;
the nitride semiconductor device further comprises a second nitride semiconductor layer formed from a nitride semiconductor including an acceptor impurity; and
the second nitride semiconductor layer is located between the first peripheral electrode and the first nitride semiconductor layer.

20. The nitride semiconductor device according to claim 19, wherein the second nitride semiconductor layer is in an electrically floating state.
